(19) United States
(12) Patent Application Publication
(10) Pub. No.: US 2025/0199407 A1
(43) Pub. Date: Jun. 19, 2025

(54) RESIST UNDERLAYER FILM-FORMING COMPOSITION CONTAINING FLUORENE SKELETON

(71) Applicant: NISSAN CHEMICAL CORPORATION, Tokyo (JP)

(72) Inventor: Shou SHIMIZU, Toyama-shi (JP)

(73) Assignee: NISSAN CHEMICAL CORPORATION, Tokyo (JP)

(21) Appl. No.: 18/848,762

(22) PCT Filed: Mar. 23, 2023
(86) PCT No.: PCT/JP2023/011405

§ 371 Date: Sep. 19, 2024

(30) Foreign Application Priority Data
Mar. 23, 2022 (JP) 2022-047111

(51) Int. Cl. G03F 7/09; C09D 179/08; H01L 21/311

(52) U.S. Cl. CPC G03F 7/094; C09D 179/08; H01L 21/31127; H01L 21/31144

(57) ABSTRACT

A resist underlayer film-forming composition for EB or EUV lithography, the resist underlayer film-forming composition including: a polymer containing a fluorene structure; and a solvent.

### TECHNICAL FIELD

The present invention relates to a resist underlayer film-forming composition for EB or EUV lithography, a resist underlayer film for EB or EUV lithography, a semiconductor processing substrate, a method for manufacturing a semiconductor element, and a method for forming a pattern.

### BACKGROUND ART

For semiconductor devices such as large scale integrated circuits (LSIs), there are demands for the formation of fine patterns as well as the improvement in integration, and a minimum pattern size in recent years has reached 100 nm or less.

The formation of fine patterns in such semiconductor devices has been implemented by shortening in the wavelength of a light source of an exposure device and improvement on resist materials. Currently, the formation of fine patterns has been performed by a liquid immersion lithography, in which exposure is performed through water with a light source that emits argon fluoride (ArF) excimer laser light having a wavelength of 193 nm, and as a resist material used for the lithography, various ArF resist materials, which use acrylic resins as a base, have been developed.

Furthermore, as a lithography technique of the next generation, electron beam (EB) lithography using an electron beam or extreme ultraviolet (EUV) lithography using, as a light source, soft X rays having a wavelength of 13.5 nm has been studied, and a pattern size has been further reduced to 30 nm or less, achieving even finer patterns.

However, along with such reduction of the pattern size, roughness of side walls of a resist pattern, that is, line edge roughness (LER) and unevenness of a resist pattern line width, that is, line width roughness (LWR) of the resist pattern have been significant, which bring concerns that these defects may adversely affect performances of a resulting device. Although various studies have been conducted to control LER and LWR of a resist pattern by optimizing an exposure device, a resist material, and process conditions, sufficient results have not been achieved. Note that, the LWR and the LER are related to each other, and the LER is improved, as the LWR is improved.

As a method for solving the aforementioned problem, for example, a method for improving LWR and LER is disclosed, the method including treating a resist pattern with an aqueous solution containing a certain ionic surfactant in a rinsing step, which is performed after developing treatment, to dissolve the roughness of the resist pattern while defects (defects such as residuals and pattern collapse) caused by the developing treatment are minimized (Patent Literature 1).

### CITATION LIST

### Patent Literature

Patent Literature 1: JP 2007-213013 A

### SUMMARY OF INVENTION

### Technical Problem

An object of the present invention is to provide a resist underlayer film-forming composition for EB or EUV lithography capable of reducing LWR of a resist pattern with EB or EUV lithography, a resist underlayer film for EB or EUV lithography, a semiconductor processing substrate, a method for manufacturing a semiconductor element, and a method for forming a pattern.

### Solution to Problem

As a result of intensive studies to solve the above-described problem, the present inventors have found that the above-described problem can be solved, and have completed the present invention including the following gist.

That is, the present invention includes the following aspects.
[1] A resist underlayer film-forming composition for EB or EUV lithography, the resist underlayer film-forming composition including:
a polymer containing a fluorene structure; and
a solvent.
[2] The resist underlayer film-forming composition for EB or EUV lithography according to [1], in which the polymer contains a partial structure represented by Formula (1),

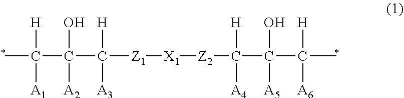

where, X₁ represents a divalent organic group having a fluorene structure,
Z₁ and Z₂ each independently represent a single bond, —O—, —C(═O)O—, or —O—CₘH₂ₘ—O— (where, m represents an integer of 1 to 6),
A₁, A₂, A₃, A₄, A₅, and A₆ each independently represent a hydrogen atom, a methyl group, or an ethyl group, and
* represents a bond.
[3] The resist underlayer film-forming composition for EB or EUV lithography according to [2], in which X₁ in Formula (1) represents a divalent organic group represented by Formula (1-A) or (1-B),

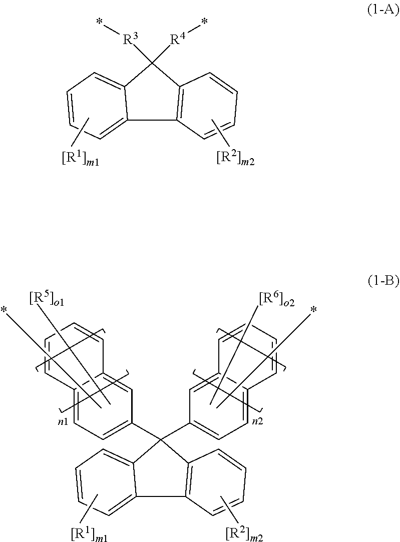

where, R¹, R², R⁵, and R⁶ each independently represent a hydroxy group, an acyl group having 1 to 6 carbon atoms, an alkoxy group having 1 to 6 carbon atoms, an alkoxycarbonyl group having 1 to 6 carbon atoms, an alkyl group having 1 to 10 carbon atoms, an aryl group having 6 to 20 carbon atoms, an alkenyl group having 2 to 20 carbon atoms, or an alkynyl group having 2 to 10 carbon atoms, and the acyl group, the alkoxy group, the alkoxycarbonyl group, the alkyl group, the aryl group, the alkenyl group, and the alkynyl group may have one or more groups selected from the group consisting of an amino group, a nitro group, a cyano group, a hydroxy group, a glycidyl group, and a carboxyl group,
R³ and R⁴ each independently represent a single bond or an alkylene group having 1 to 10 carbon atoms,
m1 and m2 each independently represent an integer of 0 to 4,
n1 and n2 each independently represent 0 or 1,
in a case where n1 is 0, o1 represents an integer of 0 to 4, and in a case where n1 is 1, o1 represents an integer of 0 to 6,
in a case where n2 is 0, o2 represents an integer of 0 to 4, and in a case where n2 is 1, o2 represents an integer of 0 to 6,
in a case where a plurality of R¹'s, a plurality of
R²'s, a plurality of R³'s, a plurality of R⁴'s, a plurality of R⁵'s, and a plurality of R⁶'s are present, each R¹, each R², each R³, each R⁴, each R⁵, and each R⁶ may be the same as or different from each other,
one R⁵ and one R⁶ may be combined to form an —O— bond, and
* represents a bond.
[4] The resist underlayer film-forming composition for EB or EUV lithography according to [2] or [3], in which the polymer further contains at least one of a partial structure represented by Formula (2-1) or a partial structure represented by Formula (2-2),

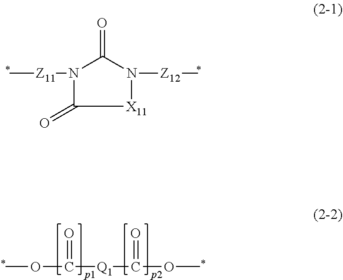

where, X₁₁ represents a group represented by any one of Formula (2-1-1), (2-1-2), or (2-1-3),
Z₁₁ and Z₁₂ each independently represent a single bond or a divalent group represented by Formula (2-1-4),
Q₁ represents a single bond or a divalent organic group, and p1 and p2 each independently represent 0 or 1,

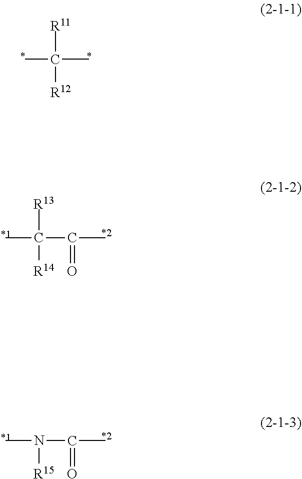

where, R¹¹ to R¹⁵ each independently represent a hydrogen atom, an alkyl group having 1 to 10 carbon atoms, which may be interrupted by an oxygen atom or a sulfur atom, an alkenyl group having 2 to 10 carbon atoms, which may be interrupted by an oxygen atom or a sulfur atom, an alkynyl group having 2 to 10 carbon atoms, which may be interrupted by an oxygen atom or a sulfur atom, a benzyl group, or a phenyl group, where the phenyl group may be substituted with at least one monovalent group selected from the group consisting of an alkyl group having 1 to 6 carbon atoms, a halogen atom, an alkoxy group having 1 to 6 carbon atoms, a nitro group, a cyano group, and an alkylthio group having 1 to 6 carbon atoms, R¹¹ and R¹² may be bonded to each other to form a ring having 3 to 6 carbon atoms, R¹³ and R¹⁴ may be bonded to each other to form a ring having 3 to 6 carbon atoms, * represents a bond, *1 represents a bond bonded to a carbon atom, *2 represents a bond bonded to a nitrogen atom,

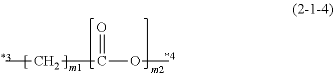

where, m1 represents an integer of 1 to 4, m2 represents 0 or 1, *3 represents a bond bonded to a nitrogen atom, and *4 represents a bond.
[5] The resist underlayer film-forming composition for EB or EUV lithography according to any one of [1] to [4], the resist underlayer film-forming composition further containing a crosslinking agent.
[6] The resist underlayer film-forming composition for EB or EUV lithography according to any one of [1] to [5], the resist underlayer film-forming composition further containing a curing catalyst.
[7] The resist underlayer film-forming composition for EB or EUV lithography according to any one of [1] to [6], in which the resist underlayer film-forming composition is used to form a resist underlayer film for EB or EUV lithography, the resist underlayer film having a film thickness of 10 nm or less.
[8] A resist underlayer film for EB or EUV lithography, in which the resist underlayer film is a cured product formed from the resist underlayer film-forming composition for EB or EUV lithography according to any one of [1] to [7].
[9] A semiconductor processing substrate including: a semiconductor substrate; and the resist underlayer film for EB or EUV lithography according to [8].
[10] A method for manufacturing a semiconductor element, the method including:
a step of forming a resist underlayer film on a semiconductor substrate by using the resist underlayer film-forming composition for EB or EUV lithography according to any one of [1] to [7]; and
a step of forming a resist film on the resist underlayer film.
[11] A method for forming a pattern, the method including:
a step of forming a resist underlayer film on a semiconductor substrate by using the resist underlayer film-forming composition for EB or EUV lithography according to any one of [1] to [7];
a step of forming a resist film on the resist underlayer film;
a step of irradiating the resist film with EB or EUV and developing the resist film to obtain a resist pattern; and
a step of etching the resist underlayer film by using the resist pattern as a mask.

### Advantageous Effects of Invention

According to the present invention, it is possible to provide the resist underlayer film-forming composition for EB or EUV lithography capable of reducing LWR of the resist pattern with EB or EUV lithography, the resist underlayer film for EB or EUV lithography, the semiconductor processing substrate, the method for manufacturing a semiconductor element, and the method for forming a pattern.

### DESCRIPTION OF EMBODIMENTS

The present inventors have studied a method capable of reducing LWR by a method other than a rinsing step. As a result, the present inventors have found that a resist underlayer film formed from a resist underlayer film-forming composition that contains a polymer containing a fluorene structure is effective for reducing LWR of a resist pattern in EB or EUV lithography.

### (Resist Underlayer Film-Forming Composition for EB or EUV Lithography)

The resist underlayer film-forming composition for EB or EUV lithography (hereinafter, simply referred to as a “resist underlayer film-forming composition” in some cases) of the present invention contains a polymer containing a fluorene structure and a solvent.

### <Polymer Containing Fluorene Structure>

The polymer containing a fluorene structure is not particularly limited as long as it contains a fluorene structure.

The fluorene structure means the following structure.

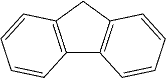 [SMILES: c1ccc2c(c1)Cc1ccccc1-2]

From the viewpoint of suitably obtaining the effects of the present invention, the polymer containing a fluorene structure preferably contains a partial structure represented by Formula (1).

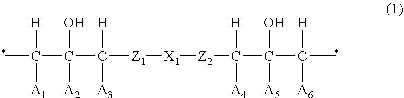

(In Formula (1), X₁ represents a divalent organic group having a fluorene structure,
Z₁ and Z₂ each independently represent a single bond, —O—, —C(═O)O—, or —O—CₘH₂ₘ—O— (where, m represents an integer of 1 to 6),
A₁, A₂, A₃, A₄, A₅, and A₆ each independently represent a hydrogen atom, a methyl group, or an ethyl group, and
* represents a bond.)

From the viewpoint of suitably obtaining the effects of the present invention, X₁ in Formula (1) preferably represents a divalent organic group represented by Formula (1-A) or (1-B).

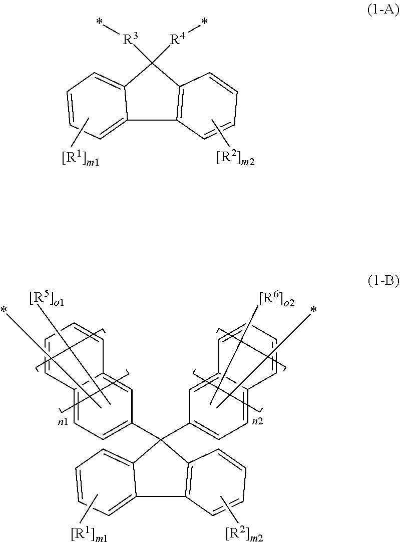

(In Formulae (1-A) and (1-B), R¹, R², R⁵, and R⁶ each independently represent a hydroxy group, an acyl group having 1 to 6 carbon atoms, an alkoxy group having 1 to 6 carbon atoms, an alkoxycarbonyl group having 1 to 6 carbon atoms, an alkyl group having 1 to 10 carbon atoms, an aryl group having 6 to 20 carbon atoms, an alkenyl group having 2 to 20 carbon atoms, or an alkynyl group having 2 to 10 carbon atoms, and the acyl group, the alkoxy group, the alkoxycarbonyl group, the alkyl group, the aryl group, the alkenyl group, and the alkynyl group may have one or more groups selected from the group consisting of an amino group, a nitro group, a cyano group, a hydroxy group, a glycidyl group, and a carboxyl group,
R³ and R⁴ each independently represent a single bond or an alkylene group having 1 to 10 carbon atoms,
m1 and m2 each independently represent an integer of 0 to 4,
n1 and n2 each independently represent 0 or 1,
in a case where n1 is 0, o1 represents an integer of 0 to 4, and in a case where n1 is 1, o1 represents an integer of 0 to 6,
in a case where n2 is 0, o2 represents an integer of 0 to 4, and in a case where n2 is 1, o2 represents an integer of 0 to 6,
in a case where a plurality of R¹'s, a plurality of R²'s, a plurality of R³'s, a plurality of R⁴'s, a plurality of R⁵'s, and a plurality of R⁶'s are present, each R¹, each R², each R³, each R⁴, each R⁵, and each R⁶ may be the same as or different from each other,
one R⁵ and one R⁶ may be combined to form an —O— bond, and
* represents a bond.)

R¹, R², R⁵, and R⁶ each independently represent a hydroxy group, an acyl group having 1 to 6 carbon atoms, an alkoxy group having 1 to 6 carbon atoms, an alkoxycarbonyl group having 1 to 6 carbon atoms, an alkyl group having 1 to 10 carbon atoms, an aryl group having 6 to 20 carbon atoms, an alkenyl group having 2 to 20 carbon atoms, or an alkynyl group having 2 to 10 carbon atoms. On the other hand, the acyl group, the alkoxy group, the alkoxycarbonyl group, the alkyl group, the aryl group, the alkenyl group, and the alkynyl group may have one or more groups selected from the group consisting of an amino group, a nitro group, a cyano group, a hydroxy group, a glycidyl group, and a carboxyl group.

Examples of the acyl group having 1 to 6 carbon atoms include a formyl group, an acetyl group, a propionyl group, a butyryl group, an isobutyryl group, a valeryl group, an isovaleryl group, and other acyl groups.

Examples of the alkoxy group having 1 to 6 carbon atoms include a methoxy group, an ethoxy group, an n-propoxy group, an isopropoxy group, an n-butoxy group, an isobutoxy group, a tert-butoxy group, a sec-butoxy group, an n-pentoxy group, a neopentoxy group, an n-hexyloxy group, an isohexyloxy group, a 3-methylpentoxy group, and other alkoxy groups.

Examples of the alkoxycarbonyl group having 1 to 6 carbon atoms include a methoxycarbonyl group, an ethoxycarbonyl group, an n-propoxycarbonyl group, an i-propoxycarbonyl group, an n-butoxycarbonyl group, an i-butoxycarbonyl group, a sec-butoxycarbonyl group, a tert-butoxycarbonyl group, an n-pentyloxycarbonyl group, an n-hexyloxycarbonyl group, and other alkoxycarbonyl groups.

Examples of the alkyl group having 1 to 10 carbon atoms include linear alkyl groups such as a methyl group, an ethyl group, a n-propyl group, a n-butyl group, a n-pentyl group, a n-hexyl group, a n-heptyl group, a n-octyl group, a n-nonyl group, and a n-decyl group; branched alkyl groups such as an isopropyl group, a sec-butyl group, a tert-butyl group, an isopentyl group, a neopentyl group, a 1-methylpentyl group, an isohexyl group, a 1-propylbutyl group, a 2-ethylhexyl group, and an isononyl group; cyclic alkyl groups such as a cyclopropyl group, a cyclobutyl group, a cyclopentyl group, a cyclohexyl group, a p-tert-butylcyclohexyl group, and an adamantyl group; and other alkyl groups.

Examples of the aryl group having 6 to 20 carbon atoms include a phenyl group, a naphthyl group, a biphenyl group, an anthracyl group, a phenanthsyl group, a pyrenyl group, and other aryl groups.

Examples of the alkenyl group having 2 to 20 carbon atoms include a vinyl group, a propenyl group, a butenyl group, and other alkenyl groups.

Examples of the alkynyl group having 2 to 10 carbon atoms include an ethynyl group, a propynyl group, a butynyl group, a pentynyl group, a hexynyl group, a heptynyl group, an octynyl group, a nonynyl group, a decynyl group, a butadiynyl group, a pentadiynyl group, a hexadiynyl group, a heptadiynyl group, an octadiynyl group, a nonadiynyl group, a decadiynyl group, and other alkynyl groups.

R³ and R⁴ each independently represent a single bond or an alkylene group having 1 to 10 carbon atoms.

Examples of the alkylene group having 1 to 10 carbon atoms include a methylene group, an ethylene group, a 1,3-propylene group, a 1-methylethylene group, a 1,4-butylene group, a 1-ethylethylene group, a 1-methylpropylene group, a 2-methylpropylene group, a 1,5-pentylene group, a 1-methylbutylene group, a 2-methylbutylene group, a 1,1-dimethylpropylene group, a 1,2-dimethylpropylene group, a 1-ethylpropylene group, a 2-ethylpropylene group, a 1,6-hexylene group, a 1,4-cyclohexylene group, a 1,8-octylene group, a 2-ethyloctylene group, a 1,9-nonylene group, a 1,10-decylene group, and other alkylene groups.

The —CₘH₂ₘ— group of —O—CₘH₂ₘ—O— in Z₁ and Z₂ may be linear or branched.

“*—Z₁-X₁—Z₂—*” in Formula (1) includes the following structures.

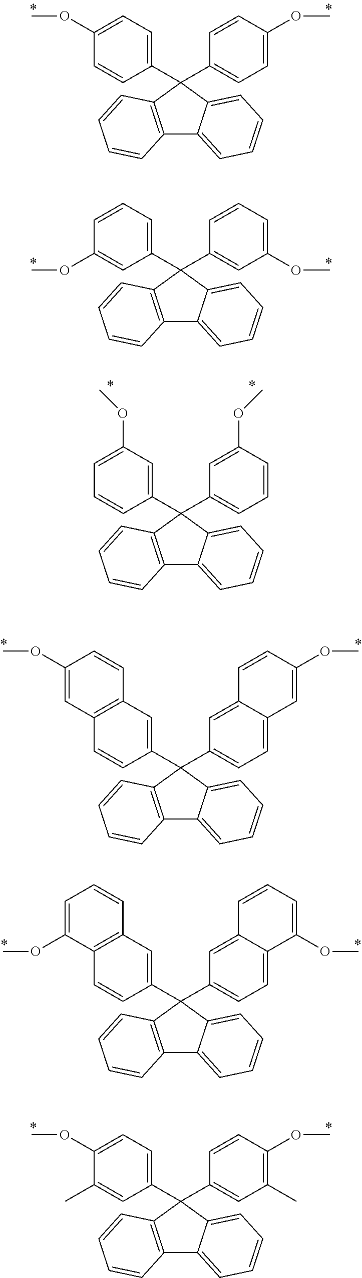

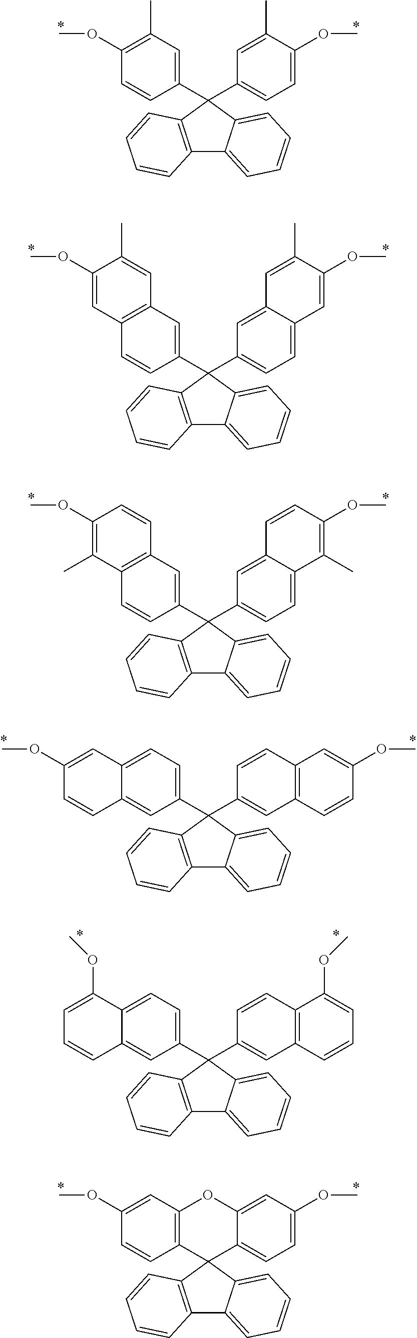

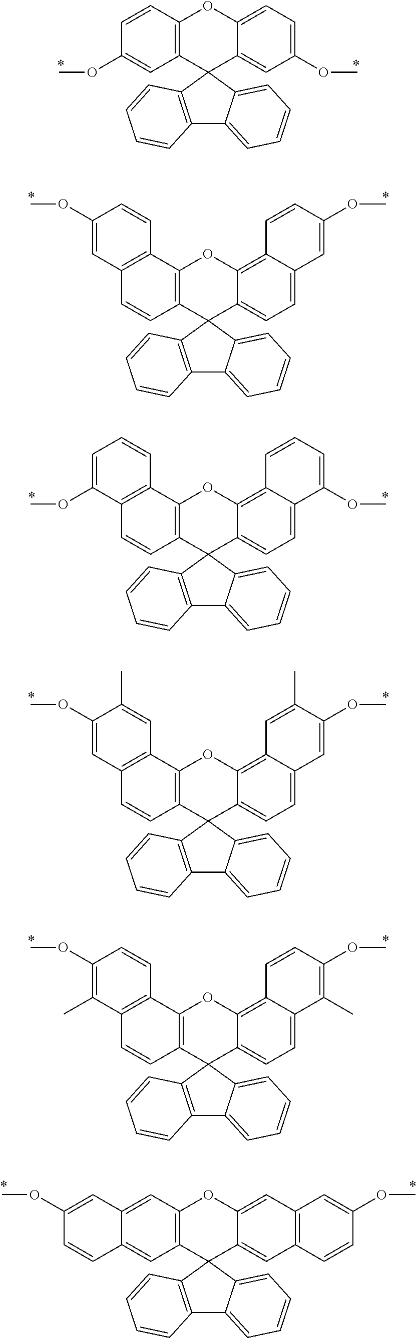

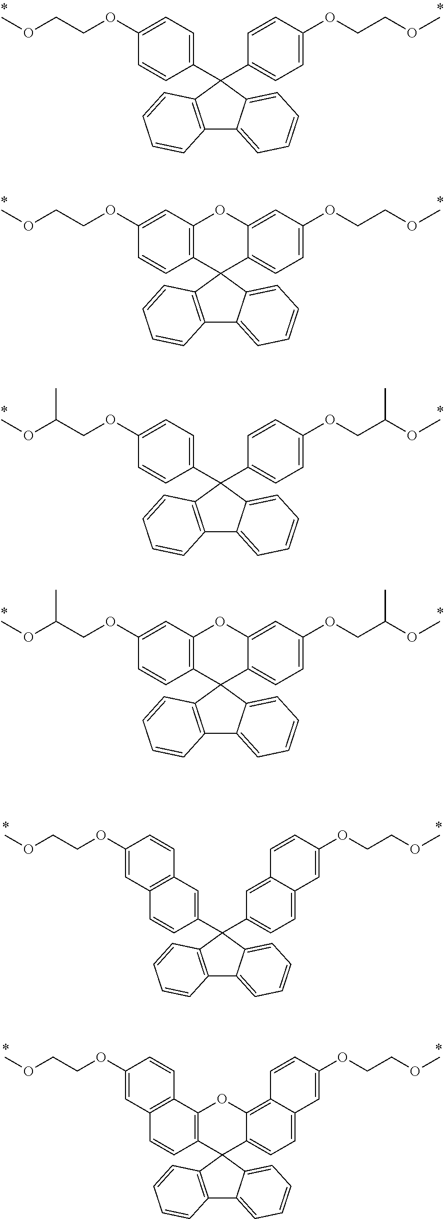

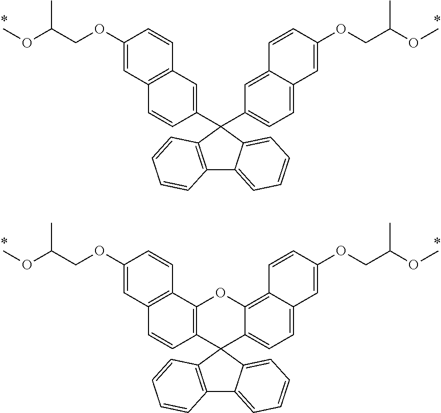

In the above-described structures, * represents a bond.

The polymer containing a fluorene structure may further contain at least one of a partial structure represented by Formula (2-1) or a partial structure represented by Formula (2-2).

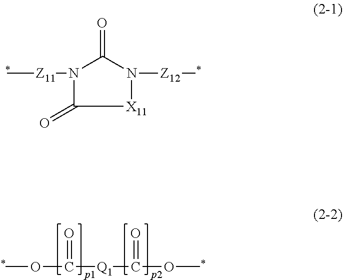

(In Formula (2-1), X₁₁ represents a group represented by any one of Formula (2-1-1), (2-1-2), or (2-1-3),
Z₁₁ and Z₁₂ each independently represent a single bond or a divalent group represented by Formula (2-1-4),
in Formula (2-2), Q₁ represents a single bond or a divalent organic group, and p1 and p2 each independently represent 0 or 1,
* represents a bond.)

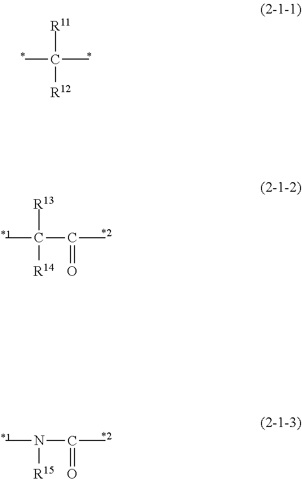

(In Formulae (2-1-1) to (2-1-3), R¹¹ to R¹⁵ each independently represent a hydrogen atom, an alkyl group having 1 to 10 carbon atoms, which may be interrupted by an oxygen atom or a sulfur atom, an alkenyl group having 2 to 10 carbon atoms, which may be interrupted by an oxygen atom or a sulfur atom, an alkynyl group having 2 to 10 carbon atoms, which may be interrupted by an oxygen atom or a sulfur atom, a benzyl group, or a phenyl group, where the phenyl group may be substituted with at least one monovalent group selected from the group consisting of an alkyl group having 1 to 6 carbon atoms, a halogen atom, an alkoxy group having 1 to 6 carbon atoms, a nitro group, a cyano group, and an alkylthio group having 1 to 6 carbon atoms, R¹¹ and R¹² may be bonded to each other to form a ring having 3 to 6 carbon atoms, R¹³ and R¹⁴ may be bonded to each other to form a ring having 3 to 6 carbon atoms, * represents a bond, *1 represents a bond bonded to a carbon atom, *2 represents a bond bonded to a nitrogen atom.)

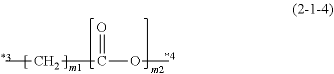

(In Formula (2-1-4), m1 represents an integer of 1 to 4, m2 represents 0 or 1, *3 represents a bond bonded to a nitrogen atom, and *4 represents a bond.)

Specific examples of the alkyl group having 1 to 10 carbon atoms include the alkyl groups exemplified for R¹, R², R⁵, and R⁶ in Formulae (1-A) and (1-B).

Specific examples of the alkenyl group having 2 to 10 carbon atoms include the alkenyl groups exemplified for R¹, R², R⁵, and R⁶ in Formulae (1-A) and (1-B).

Specific examples of the alkynyl group having 2 to 10 carbon atoms include the alkynyl groups exemplified for R¹, R², R⁵, and R⁶ in Formulae (1-A) and (1-B).

Q₁ is not particularly limited as long as it is a divalent organic group, and examples thereof include a divalent organic group having 1 to 20 carbon atoms. Examples of the divalent organic group having 1 to 10 carbon atoms include an alkylene group having 1 to 10 carbon atoms, which may be interrupted by an oxygen atom or a sulfur atom.

Examples of the alkylene group having 1 to 10 carbon atoms, which may be interrupted by an oxygen atom or a sulfur atom, include an alkylene group represented by the following (Q1-1).

*—CₖH₂ₖ-Q₁₁-CₘH₂ₘ-Q₁₂-CₙH₂ₙ—* (Q1-1)

(In Formula (Q1-1), Q₁₁ and Q₁₂ each independently represent a single bond, an oxygen atom, or a sulfur atom, and k, m, and n each independently represent an integer of 0 to 10, and k+m+n represents an integer of 1 to 10, where, in a case where k is 0, Q₁₁ represents a single bond, and in a case where n is 0, Q₁₂ represents a single bond.)

In a case where k, m, and n are each 1 or more, —CₖH₂ₖ—, —CₘH₂ₘ—, and —CₙH₂ₙ— each represent an alkylene group. The alkylene group may be linear or branched.

Q₁ may be a group represented by Formula (T).

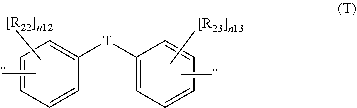

(In Formula (T), T represents a single bond, an oxygen atom, a sulfur atom, a carbonyl group, or an alkylene group having 1 to 10 carbon atoms, which may be substituted,
R₂₂ and R₂₃ each independently represent an alkyl group having 1 to 10 carbon atoms, which may be substituted,
n12 and n13 each independently represent an integer of 0 to 4,
in a case where two or more R₂₂'s are present, two or more R₂₂'s may be the same as or different from each other,
in a case where two or more R₂₃'s are present, two or more R₂₃'s may be the same as or different from each other, and
* represents a bond.)

Examples of a substituent of the alkylene group having 1 to 10 carbon atoms, which may be substituted in T of Formula (T) include a fluorine atom. The number of substituents in the alkylene group having 1 to 10 carbon atoms may be one or may be two or more.

Examples of a substituent of the alkyl group having 1 to 10 carbon atoms, which may be substituted in R₂₂ and R²³ of Formula (T) include a fluorine atom. The number of substituents in the alkyl group having 1 to 10 carbon atoms may be one or may be two or more.

Examples of Formula (2-1) include the following structures.

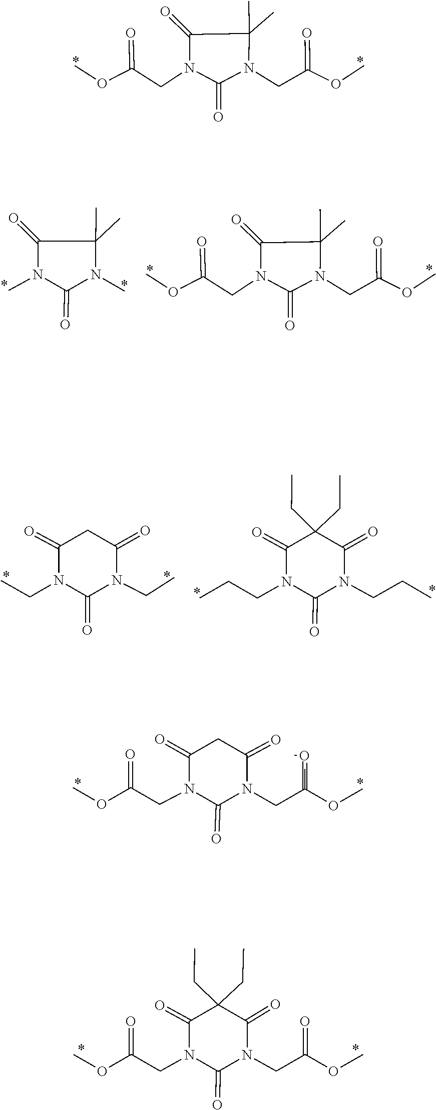

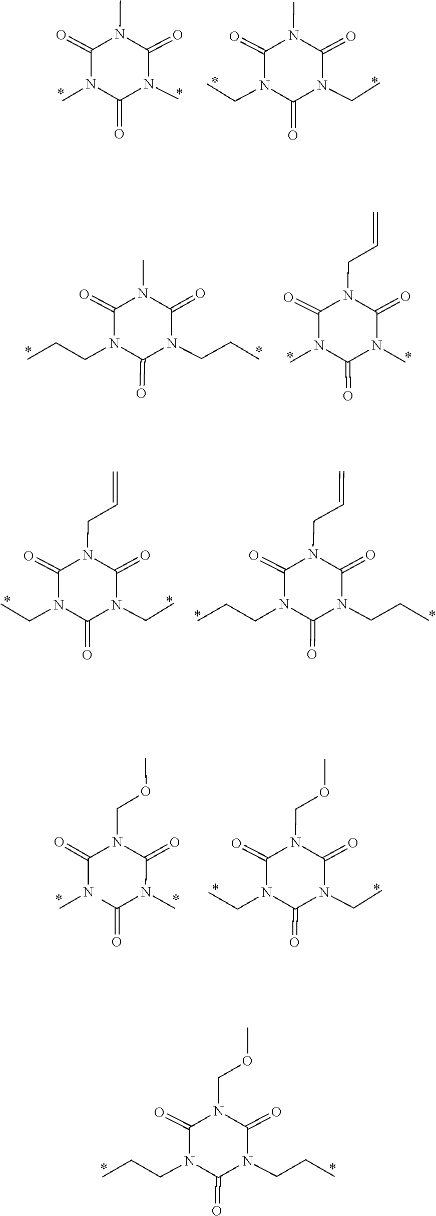

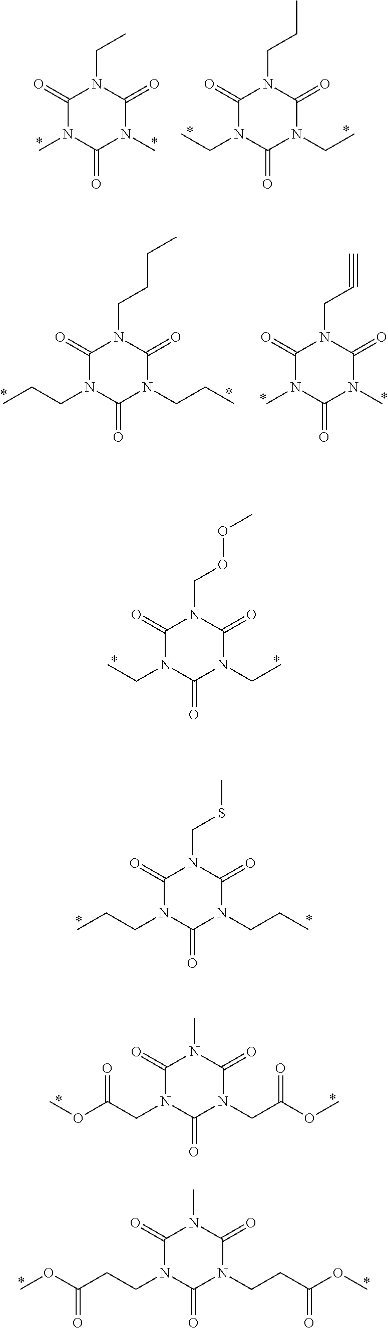

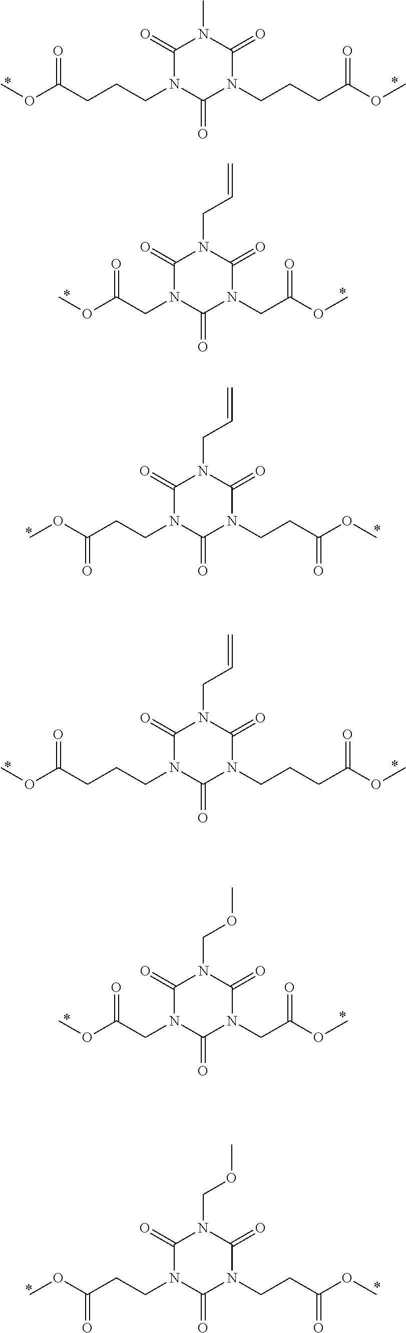

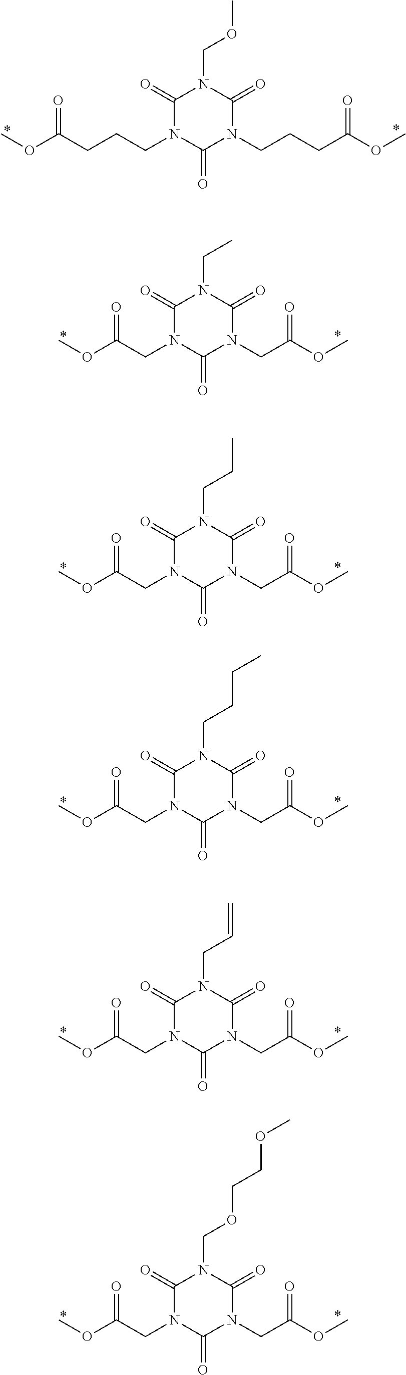

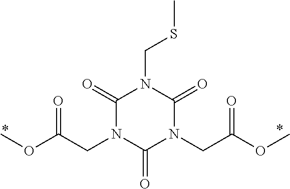

In the above-described structures, * represents a bond.

Examples of Q₁ in Formula (2-2) include the following structures.

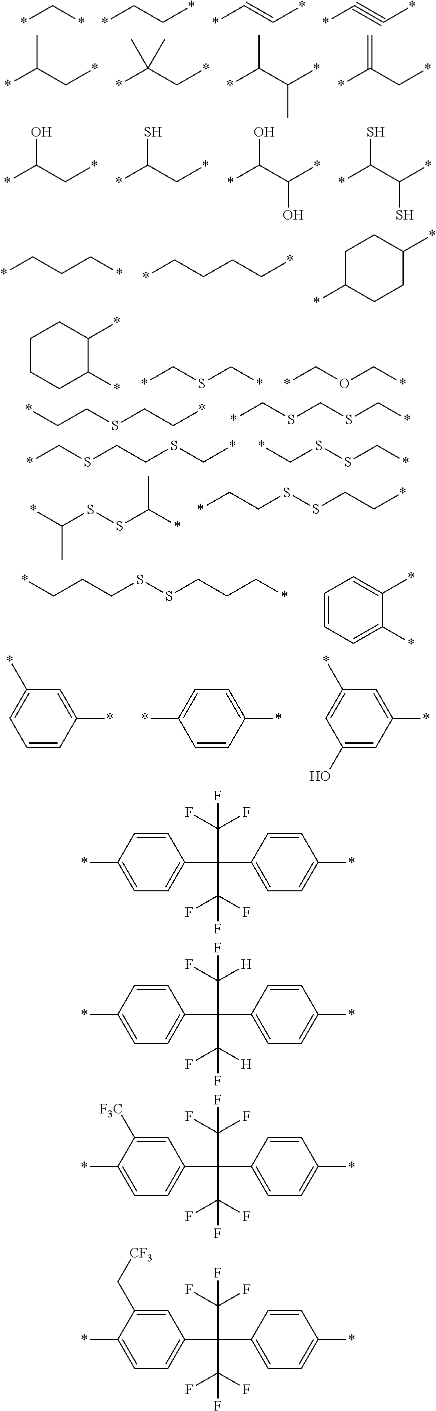

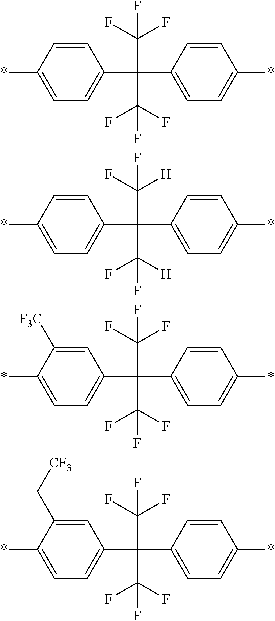

In the above-described structures, * represents a bond.

The polymer containing a fluorene structure may further have, at a terminal, an aliphatic ring which contains a carbon-carbon bond that may be interrupted by a heteroatom. The aliphatic ring may be substituted with a substituent.

The polymer containing a fluorene structure is, for example, a linear polymer. The polymer that is a linear polymer and contains a fluorene structure is preferable to have the aliphatic rings at both terminals.

Examples of the substituent in the aliphatic ring which may be substituted with a substituent and contains a carbon-carbon bond that may be interrupted by a heteroatom include a hydroxy group, a carboxy group, an alkyl group having 1 to 6 carbon atoms, an acyl group having 1 to 6 carbon atoms, an alkoxy group having 1 to 6 carbon atoms, an alkyloxycarbonyl group having 2 to 6 carbon atoms, and other substituents.

Examples of the size of the aliphatic ring include a 3-membered ring to a 10-membered ring.

The aliphatic ring may be a monocyclic ring or a polycyclic ring.

The aliphatic ring may be a saturated aliphatic ring or an unsaturated aliphatic ring.

The total number of carbon atoms of the aliphatic ring which may be substituted with a substituent and contains a carbon-carbon bond that may be interrupted by a heteroatom is, for example, 6 to 15.

In a case where the aliphatic ring which contains a carbon-carbon bond that may be interrupted by a heteroatom and is contained in the polymer containing a fluorene structure is represented as a monovalent organic group, the aliphatic ring is represented by, for example, Formula (Z).

Z—* (Z)

(In Formula (Z), Z represents a monovalent organic group formed by removing one hydrogen atom from an aliphatic ring which may be substituted with a substituent and contains a carbon-carbon bond that may be interrupted by a heteroatom, and * represents a bond.)

Examples of Z in Formula (Z) include the following structures.

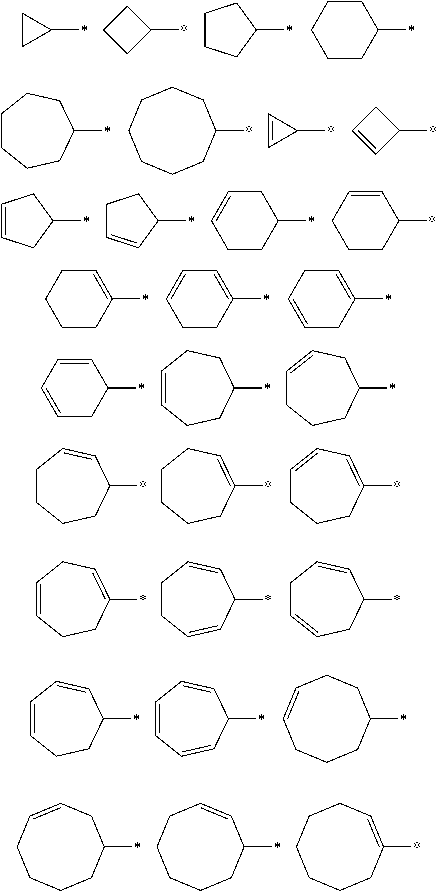

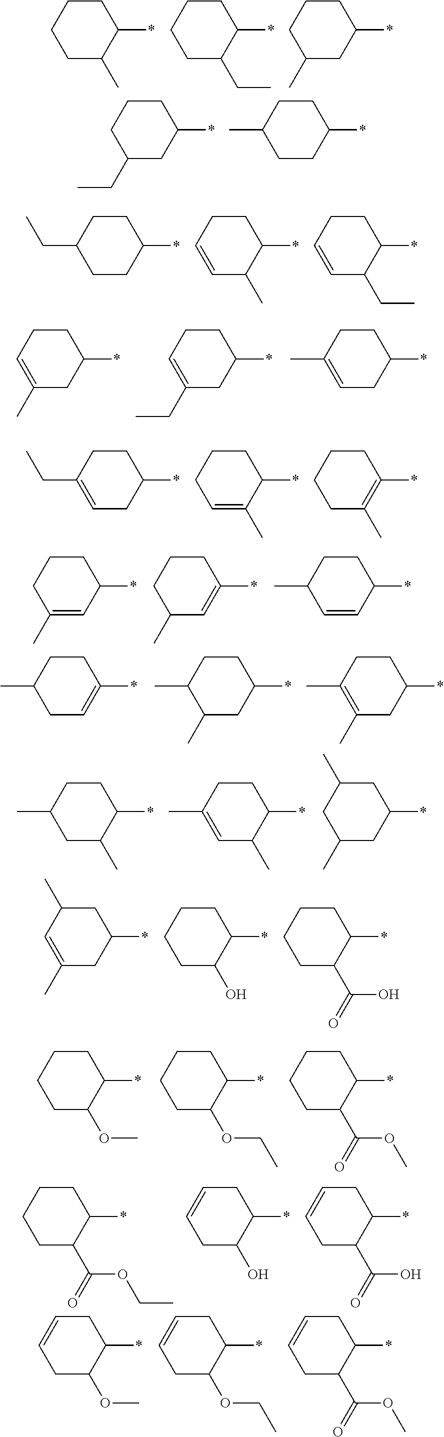

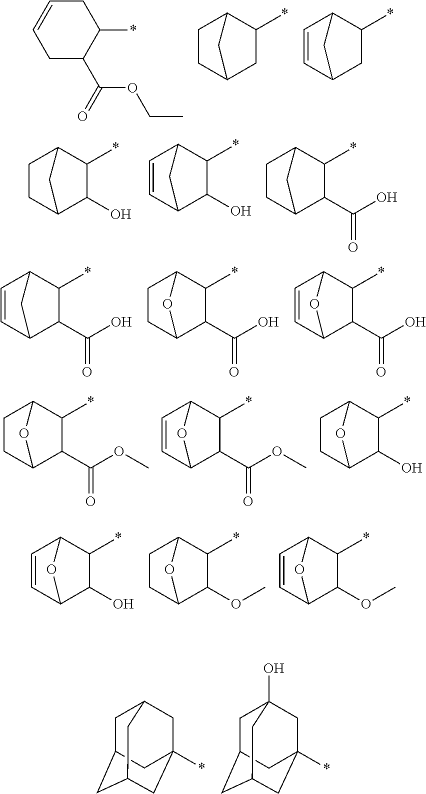

In the structures, * represents a bond.

A molecular weight of the polymer containing a fluorene structure is not particularly limited, but a weight-average molecular weight by gel permeation chromatography (hereinafter, may be abbreviated as GPC) is preferably 1,500 to 100,000, and more preferably 2,000 to 50,000.

### <<Method for Producing Polymer Containing Fluorene Structure>>

The polymer containing a fluorene structure can be produced by using, for example, a monomer containing a fluorene structure.

A method for producing a polymer containing a fluorene structure is not particularly limited, and examples thereof include the following methods (i) to (vi).
(i): a method for reacting a dihydroxy compound represented by Formula (A1-1) with a diepoxy compound having two epoxy groups
(ii): a method for reacting a dihydroxy compound represented by Formula (A1-1), a diepoxy compound having two epoxy groups, and a monocarboxy compound having one carboxy group.
(iii): a method for reacting a diepoxy compound represented by Formula (A1-2) with a dicarboxy compound having two carboxy groups
(iv): a method for reacting a diepoxy compound represented by Formula (A1-2), a dicarboxy compound having two carboxy groups, and a monocarboxy compound having one carboxy group.
(v): a method for reacting a diepoxy compound represented by Formula (A1-2) with a dihydroxy compound having two hydroxy groups that can react with epoxy groups
(vi): a method for reacting a diepoxy compound represented by Formula (A1-2), a dihydroxy compound having two hydroxy groups that can react with epoxy groups, and a monocarboxy compound having one carboxy group.

Note that, in (i) and (ii), a dihydroxy compound having two hydroxy groups other than the dihydroxy compound represented by Formula (A1-1) may be used in combination.

In addition, in (i) and (ii), a dicarboxy compound having two carboxy groups may be used in combination.

In (iii) and (iv), a diepoxy compound having two epoxy groups other than the diepoxy compound represented by Formula (A1-2) may be used in combination.

In addition, in (iii) and (iv), a dihydroxy compound having two hydroxy groups may be used in combination.

In (v) and (vi), a diepoxy compound having two epoxy groups other than the diepoxy compound represented by Formula (A1-2) may be used in combination.

In addition, in (v) and (vi), a dicarboxy compound having two carboxy groups may be used in combination.

By using the monocarboxy compound, a residue obtained by removing a carboxy group from the monocarboxy compound can be introduced into a terminal of the polymer.

The hydroxy group that reacts when the polymer is produced is preferably a phenolic hydroxy group. The phenolic hydroxy group means a hydroxy group directly bonded to an aromatic hydrocarbon ring. Examples of the aromatic hydrocarbon ring include benzene rings, naphthalene rings, anthracene rings, and other aromatic hydrocarbon rings.

In the polymerization reaction, a catalyst may be used to accelerate the reaction. The catalyst includes, for example, a quaternary phosphonium salt such as tetrabutylphosphonium bromide or ethyltriphenylphosphonium bromide, and a quaternary ammonium salt such as benzyltriethylammonium chloride. As the use amount of the catalyst, an appropriate amount can be selected and used from a range of 0.1 to 10% by mass with respect to the total mass of a raw material of a polymer used in the reaction. As a temperature and time for the polymerization reaction, for example, optimum conditions can be selected from a range of 80° C. to 160° C. and 2 to 50 hours.

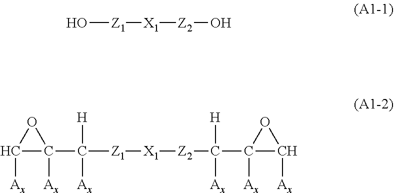

(In Formula (A1-1), X₁, Z₁, and Z₂ each have the same meanings as X₁, Z₁, and Z₂ in Formula (1), respectively,
in Formula (A1-2), X₁, Z₁, and Z₂ each have the same meanings as X₁, Z₁, and Z₂ in Formula (1), respectively, and Ax's each independently represent a hydrogen atom, a methyl group, or an ethyl group.)

In Formula (A1-1), X₁ preferably represents a divalent organic group represented by Formula (1-A) or (1-B).

In Formula (A1-1), Z₁ and Z₂ are preferably single bonds.

Examples of the compound represented by Formula (A1-1) include the following compounds.

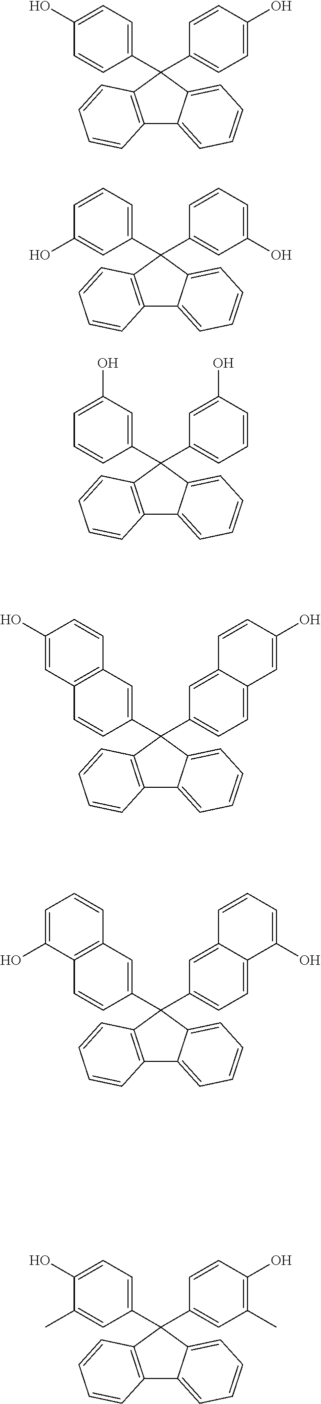

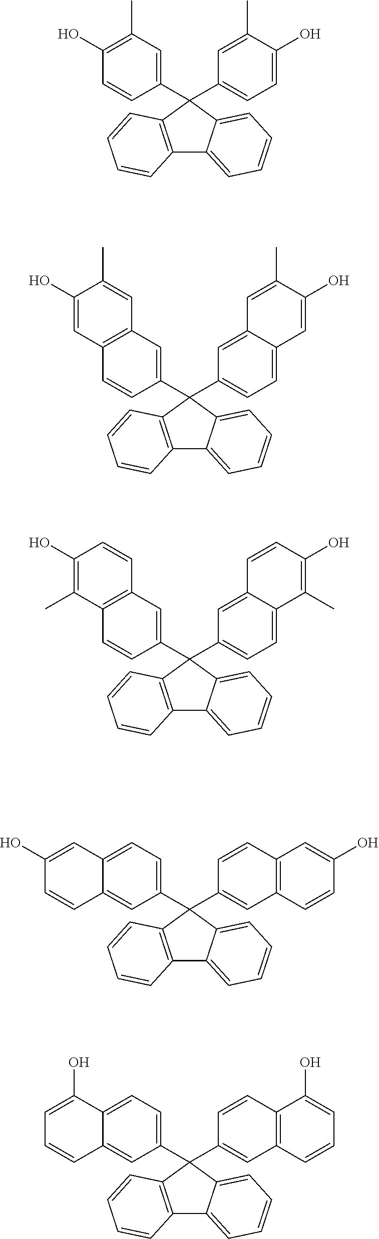 [SMILES: Cc1cc(C2(c3ccc(O)c(C)c3)c3ccccc3-c3ccccc32)ccc1O ; Cc1cc2cc(C3(c4ccc5cc(O)c(C)cc5c4)c4ccccc4-c4ccccc43)ccc2cc1O ; Cc1c(O)ccc2cc(C3(c4ccc5c(C)c(O)ccc5c4)c4ccccc4-c4ccccc43)ccc12 ; Oc1ccc2cc(C3(c4ccc5cc(O)ccc5c4)c4ccccc4-c4ccccc43)ccc2c1 ; Oc1cccc2cc(C3(c4ccc5c(O)cccc5c4)c4ccccc4-c4ccccc43)ccc12]

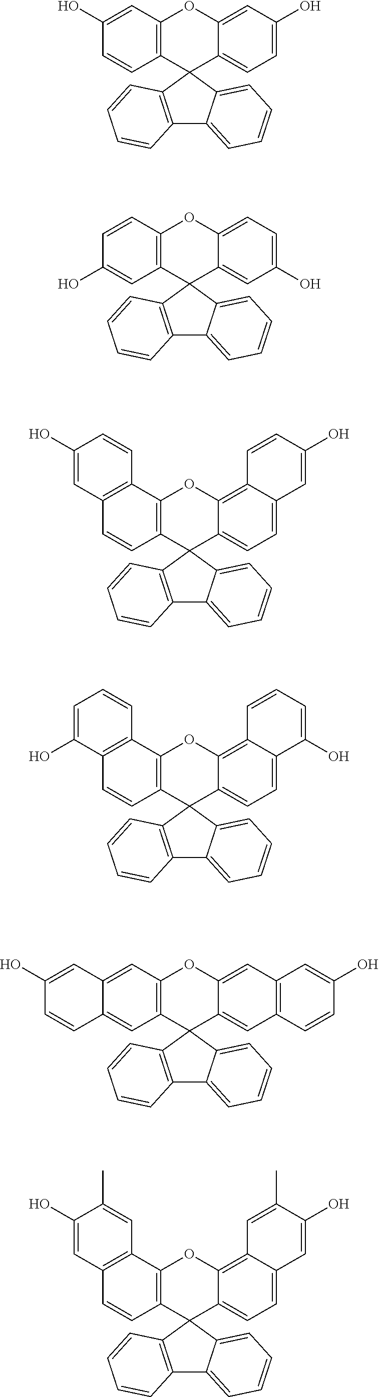 [SMILES: Oc1ccc2c(c1)Oc1cc(O)ccc1C21c2ccccc2-c2ccccc21 ; Oc1ccc2c(c1)C1(c3cc(O)ccc3O2)c2ccccc2-c2ccccc21 ; Oc1ccc2c3c(ccc2c1)C1(c2ccccc2-c2ccccc21)c1ccc2cc(O)ccc2c1O3 ; Oc1cccc2c3c(ccc12)C1(c2ccccc2-c2ccccc21)c1ccc2c(O)cccc2c1O3 ; Oc1ccc2cc3c(cc2c1)Oc1cc2cc(O)ccc2cc1C31c2ccccc2-c2ccccc21 ; Cc1cc2c3c(ccc2cc1O)C1(c2ccccc2-c2ccccc21)c1ccc2cc(O)c(C)cc2c1O3]

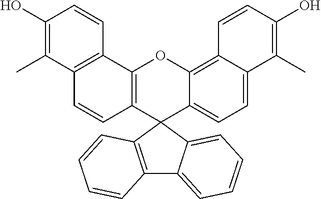 [SMILES: Cc1c(O)ccc2c3c(ccc12)C1(c2ccccc2-c2ccccc21)c1ccc2c(C)c(O)ccc2c1O3]

Examples of the compound represented by Formula (A1-2) include the following compounds.

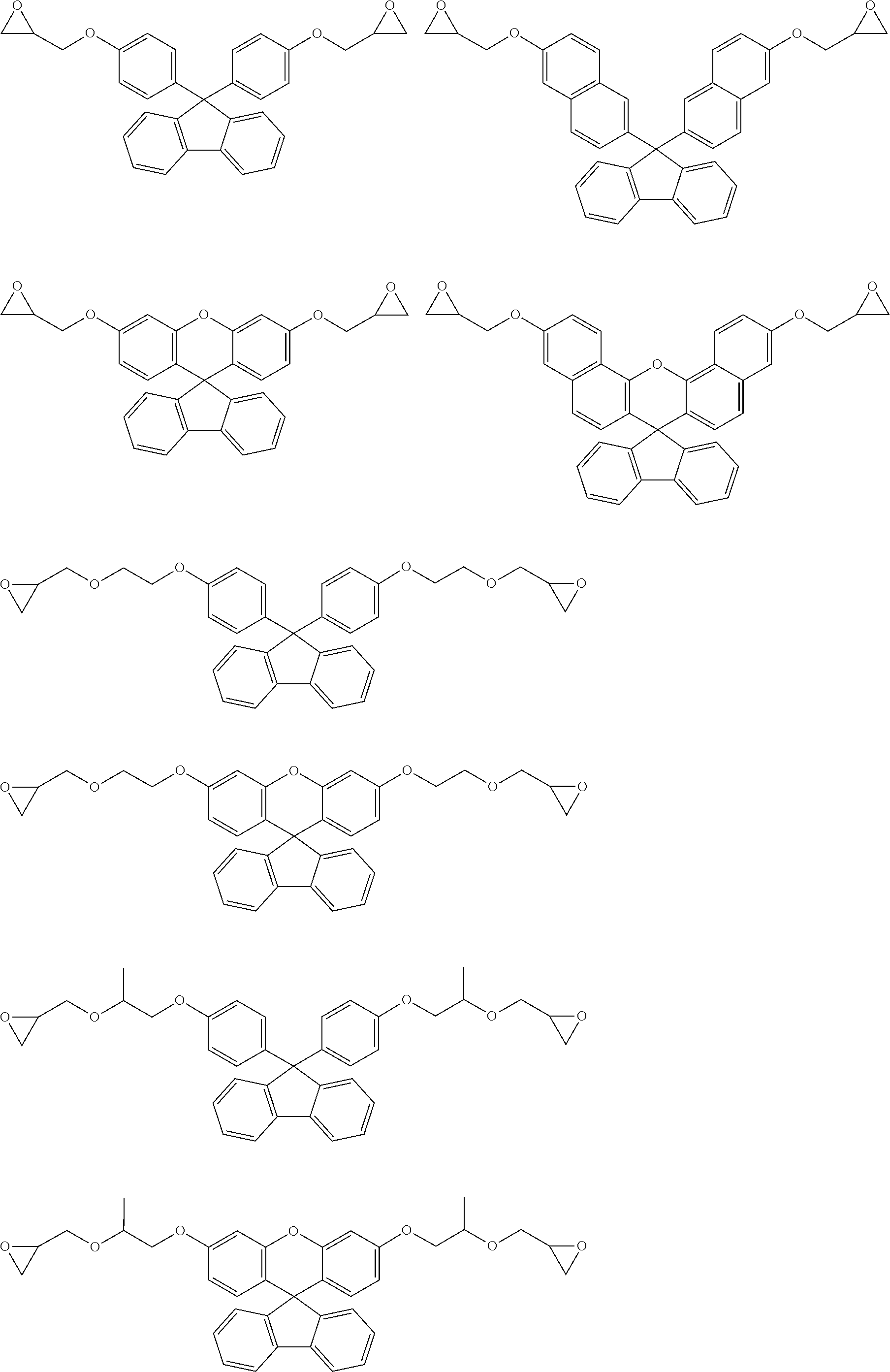

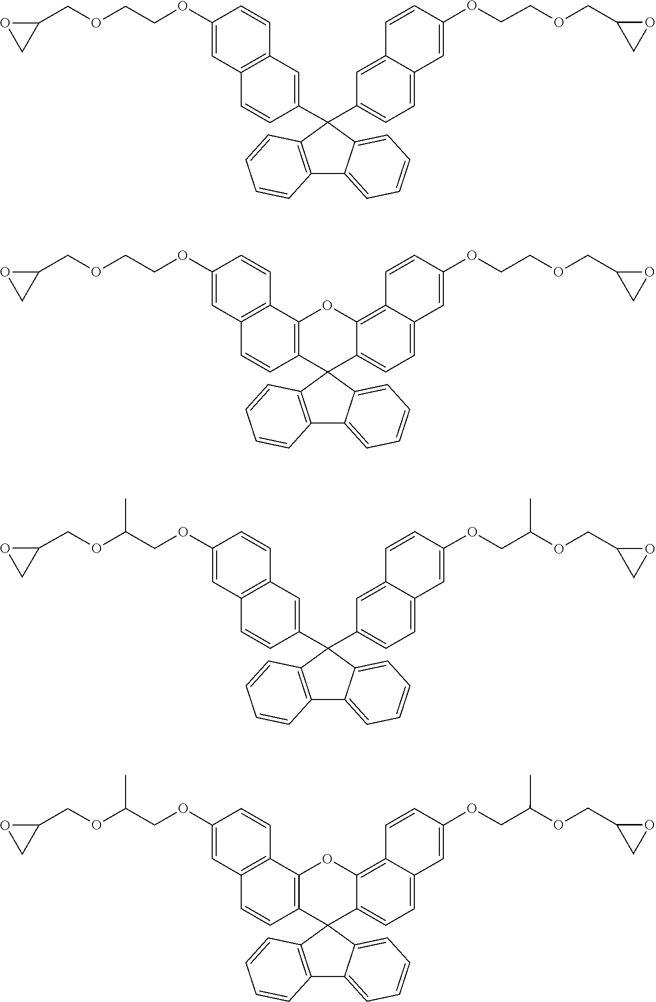 [SMILES: c1ccc2c(c1)-c1ccccc1C2(c1ccc2cc(OCCOCC3CO3)ccc2c1)c1ccc2cc(OCCOCC3CO3)ccc2c1 ; c1ccc2c(c1)-c1ccccc1C21c2ccc3cc(OCCOCC4CO4)ccc3c2Oc2c1ccc1cc(OCCOCC3CO3)ccc21 ; CC(COc1ccc2cc(C3(c4ccc5cc(OCC(C)OCC6CO6)ccc5c4)c4ccccc4-c4ccccc43)ccc2c1)OCC1CO1 ; CC(COc1ccc2c3c(ccc2c1)C1(c2ccccc2-c2ccccc21)c1ccc2cc(OCC(C)OCC4CO4)ccc2c1O3)OCC1CO1]

Examples of the diepoxy compound include a compound represented by Formula (B1).

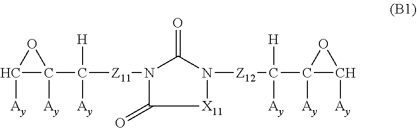

(In Formula (B1), X₁₁, Z₁₁, and Z₁₂ each have the same meanings as X₁₁, Z₁₁, and Z₁₂ in Formula (2-1), respectively, and Ay's each independently represent a hydrogen atom, a methyl group, or an ethyl group.)

Examples of the compound represented by Formula (B1) include the following compounds.

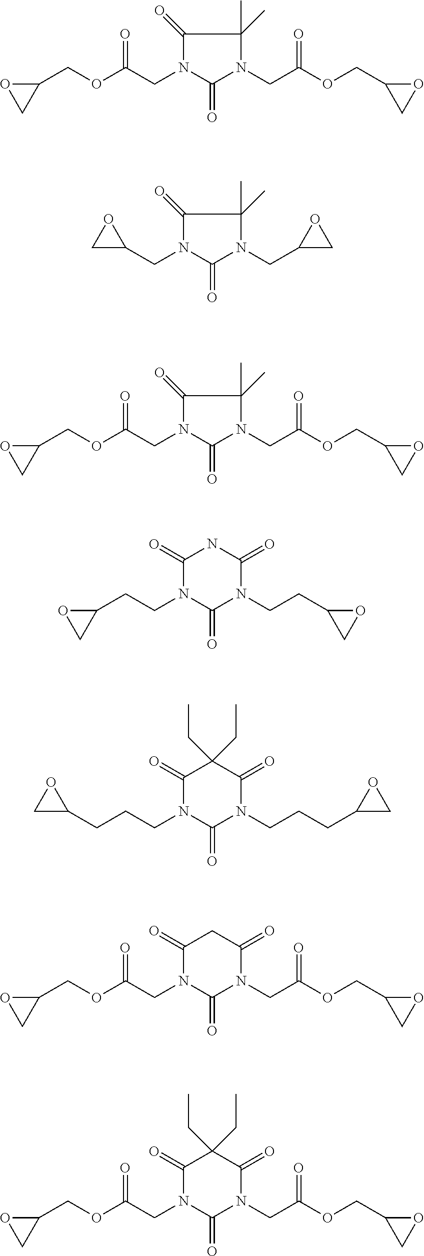

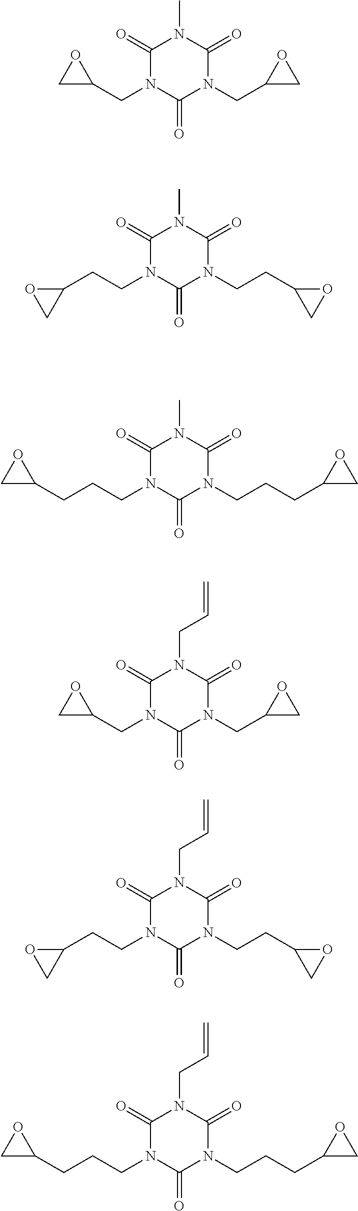

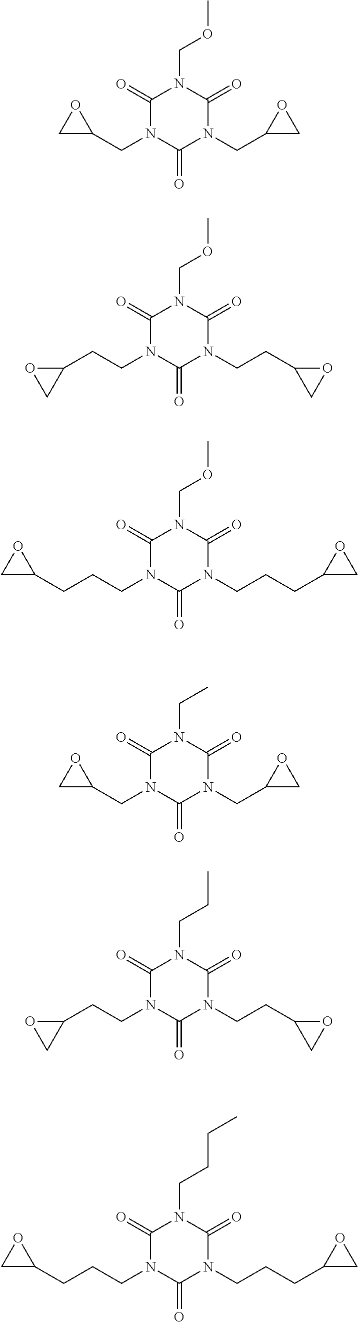

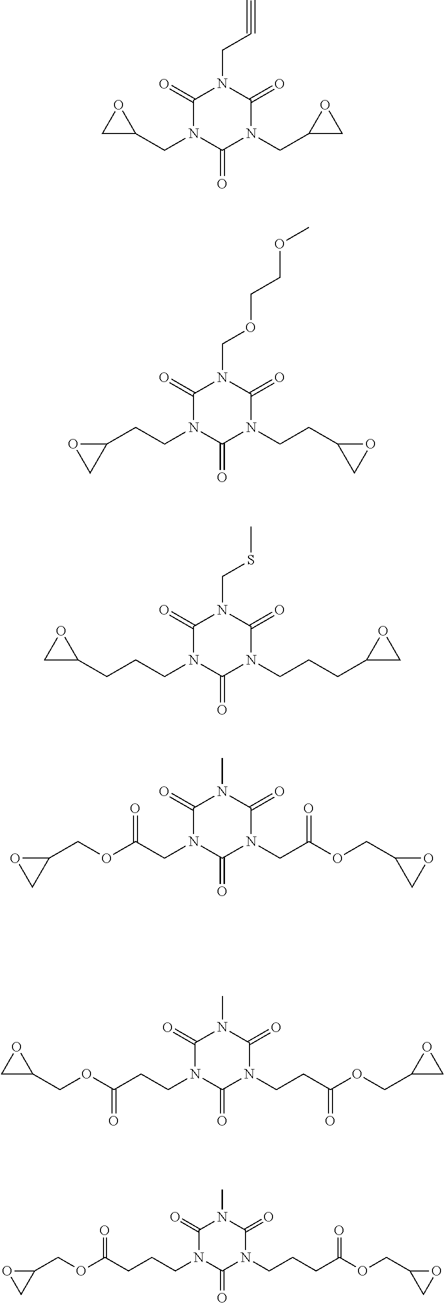 [SMILES: C#CCn1c(=O)n(CC2CO2)c(=O)n(CC2CO2)c1=O ; COCCOCn1c(=O)n(CCC2CO2)c(=O)n(CCC2CO2)c1=O ; CSCn1c(=O)n(CCCC2CO2)c(=O)n(CCCC2CO2)c1=O ; Cn1c(=O)n(CC(=O)OCC2CO2)c(=O)n(CC(=O)OCC2CO2)c1=O ; Cn1c(=O)n(CCC(=O)OCC2CO2)c(=O)n(CCC(=O)OCC2CO2)c1=O ; Cn1c(=O)n(CCCC(=O)OCC2CO2)c(=O)n(CCCC(=O)OCC2CO2)c1=O]

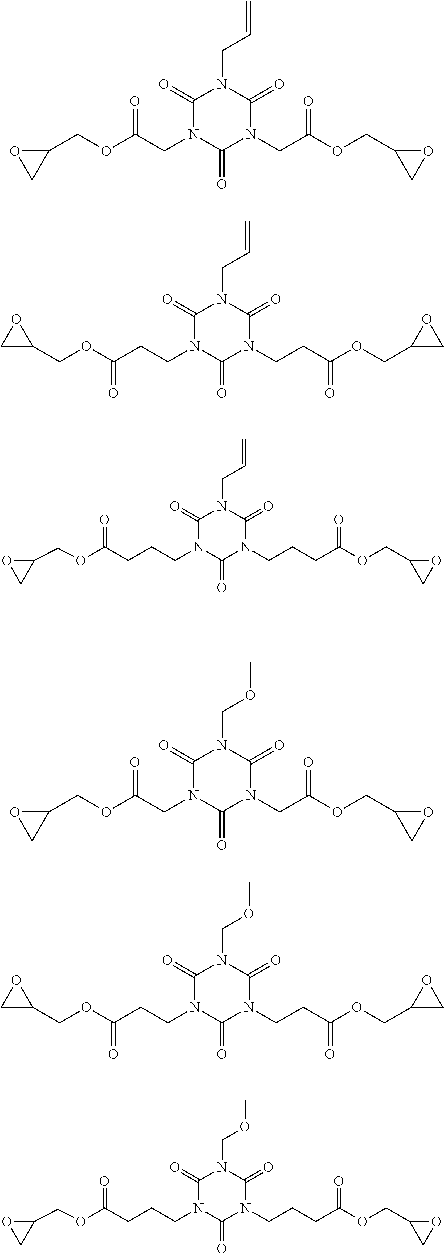 [SMILES: C=CCn1c(=O)n(CC(=O)OCC2CO2)c(=O)n(CC(=O)OCC2CO2)c1=O ; C=CCn1c(=O)n(CCC(=O)OCC2CO2)c(=O)n(CCC(=O)OCC2CO2)c1=O ; C=CCn1c(=O)n(CCCC(=O)OCC2CO2)c(=O)n(CCCC(=O)OCC2CO2)c1=O ; COCn1c(=O)n(CC(=O)OCC2CO2)c(=O)n(CC(=O)OCC2CO2)c1=O ; COCn1c(=O)n(CCC(=O)OCC2CO2)c(=O)n(CCC(=O)OCC2CO2)c1=O ; COCn1c(=O)n(CCCC(=O)OCC2CO2)c(=O)n(CCCC(=O)OCC2CO2)c1=O]

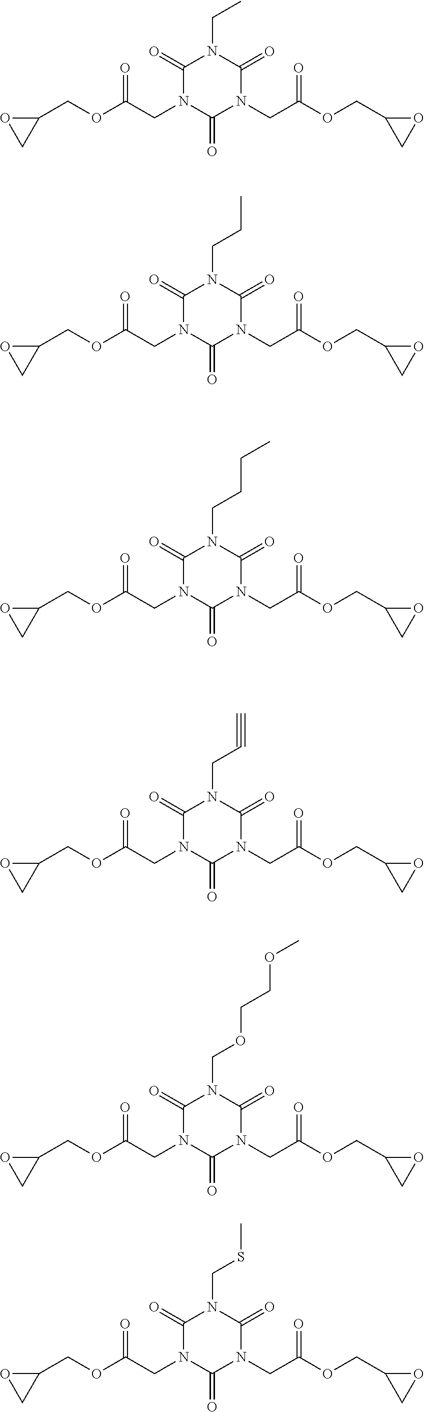

Examples of a diepoxy compound having two epoxy groups other than the diepoxy compound represented by Formula (A₁-2) include diepoxy compounds described below.

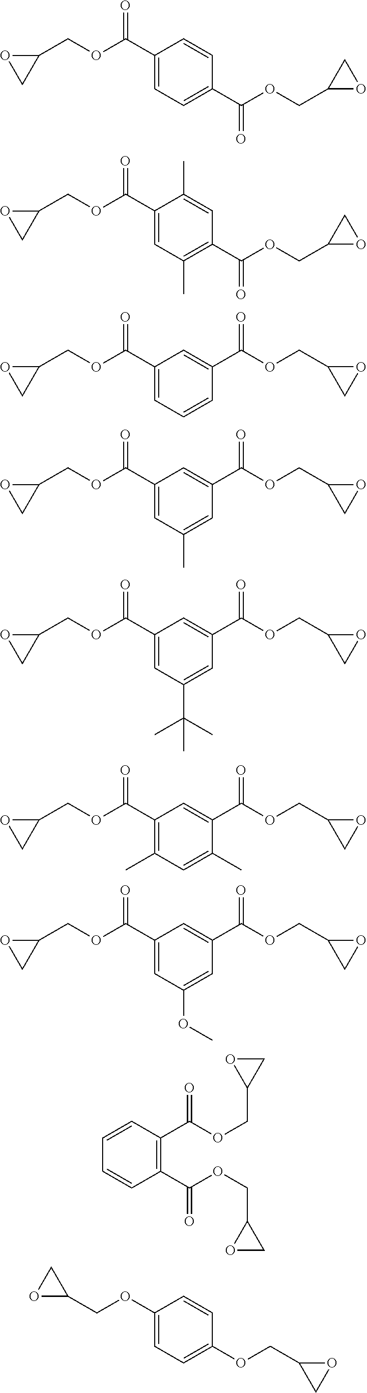

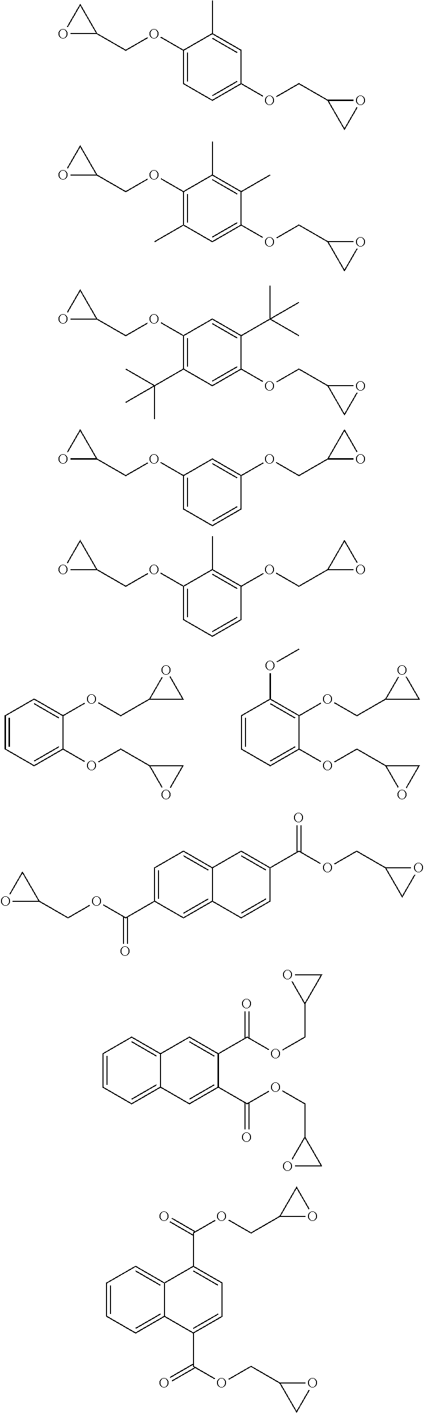

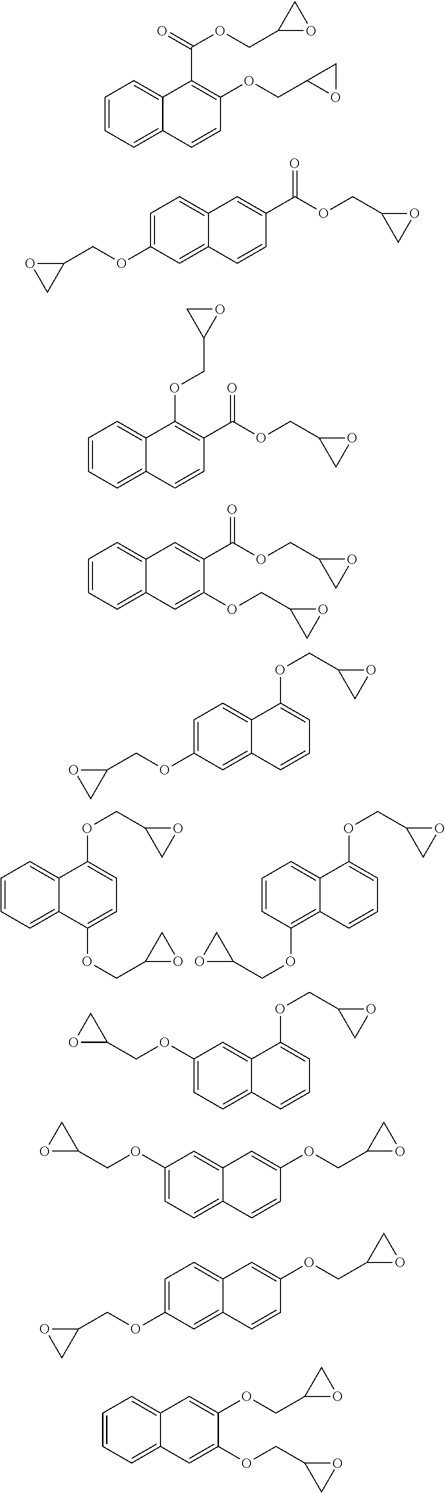

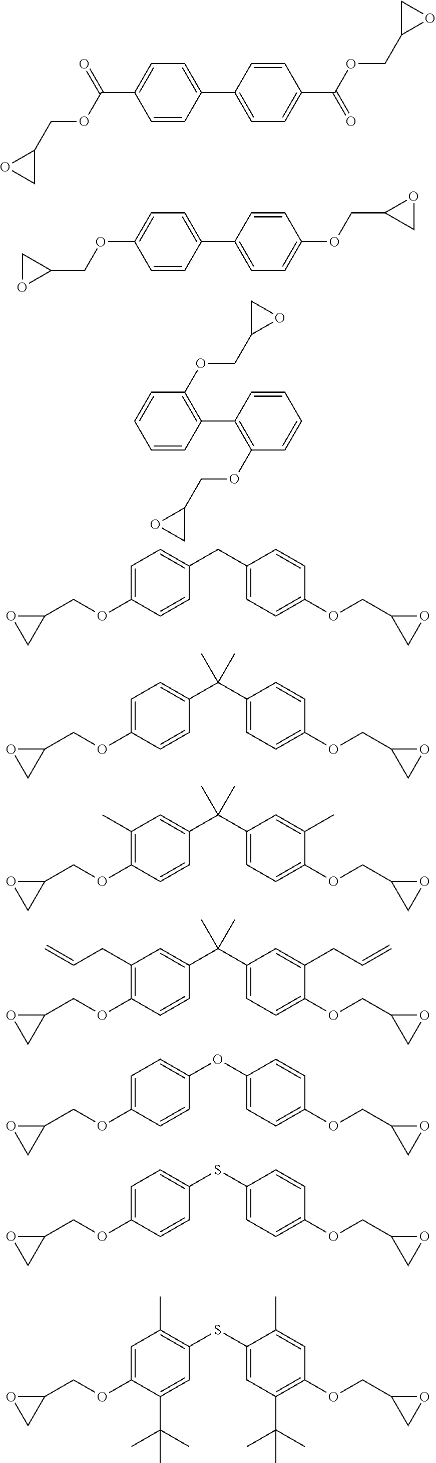

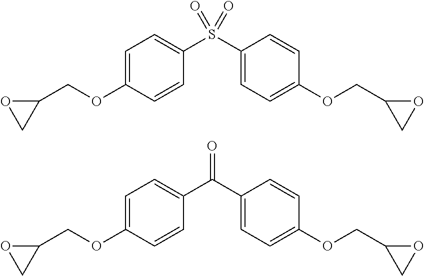 [SMILES: O=S(=O)(c1ccc(OCC2CO2)cc1)c1ccc(OCC2CO2)cc1 ; O=C(c1ccc(OCC2CO2)cc1)c1ccc(OCC2CO2)cc1]

Examples of the dicarboxy compound having two carboxy groups include a compound represented by Formula (C1).

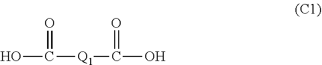

(In Formula (C1), Q₁ has the same meaning as Q₁ in Formula (2-2).)

Examples of the dihydroxy compound having two hydroxy groups that can react with epoxy groups include a compound represented by Formula (C2).

HO-Q₁-OH (C2)

(In Formula (C2), Q₁ has the same meaning as Q₁ in Formula (2-2).)

Examples of the compound represented by Formula (C1) include the following compounds.

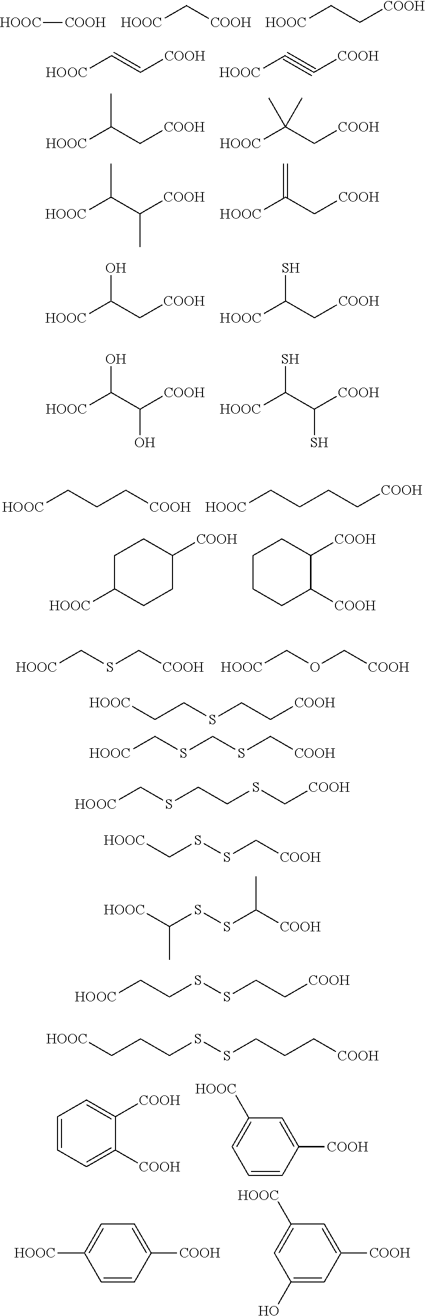

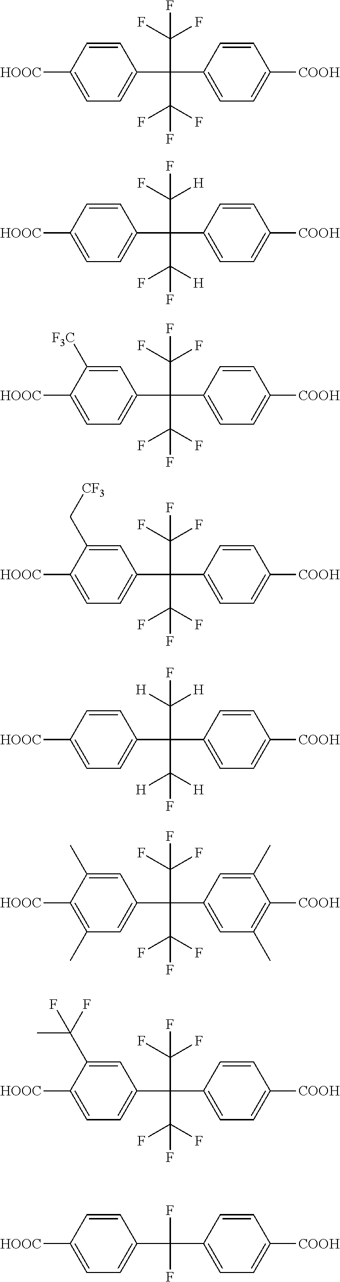

Examples of the compound represented by Formula (C2) include the following compounds.

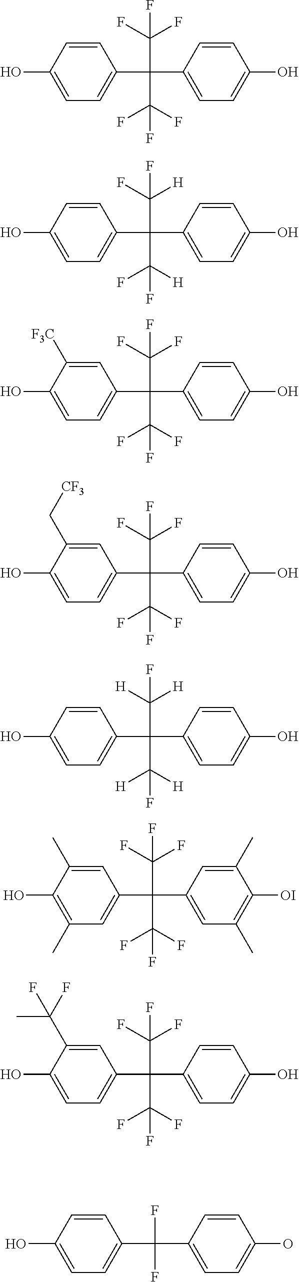

In addition, the following compounds may be used as monomers for producing the polymer containing a fluorene structure.

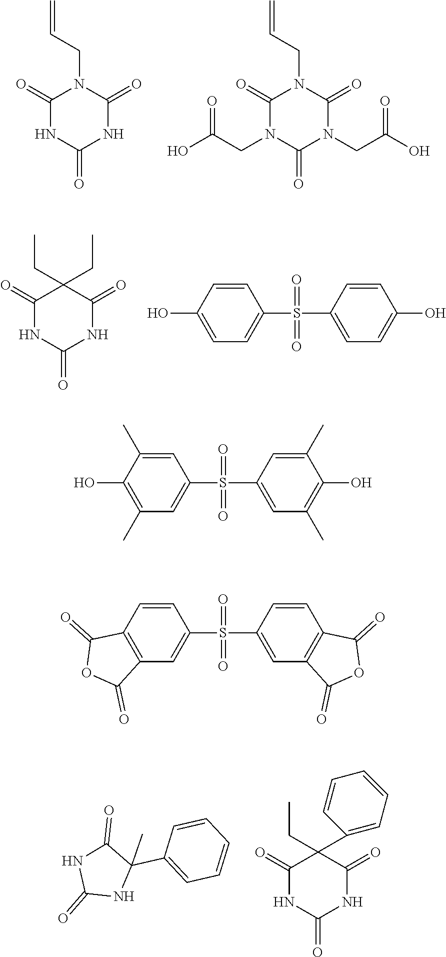

Examples of the monocarboxy compound having one carboxy group include a compound represented by Formula (Dl).

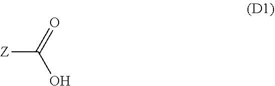

(In Formula (Dl), Z has the same meaning as Z in Formula (Z).)

Examples of the compound represented by Formula (Dl) include the following compounds.

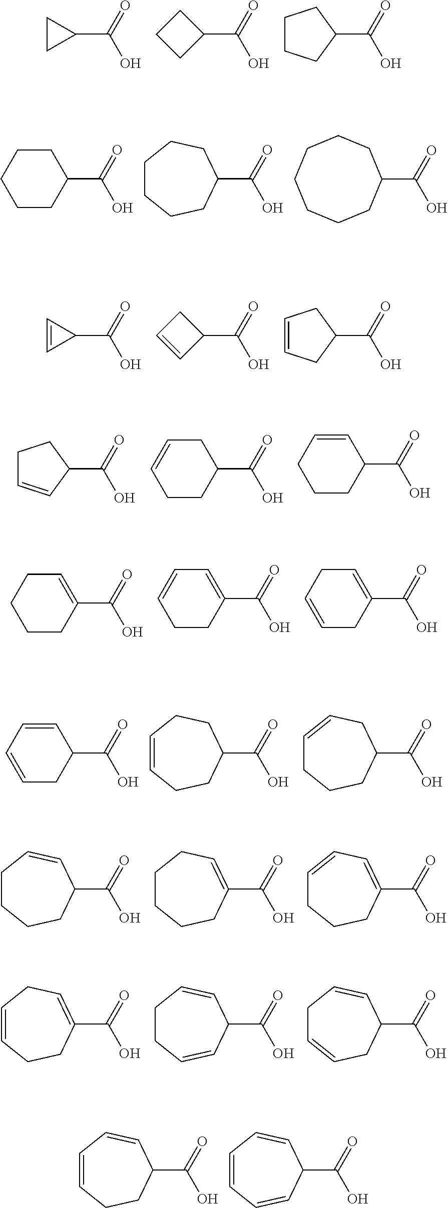

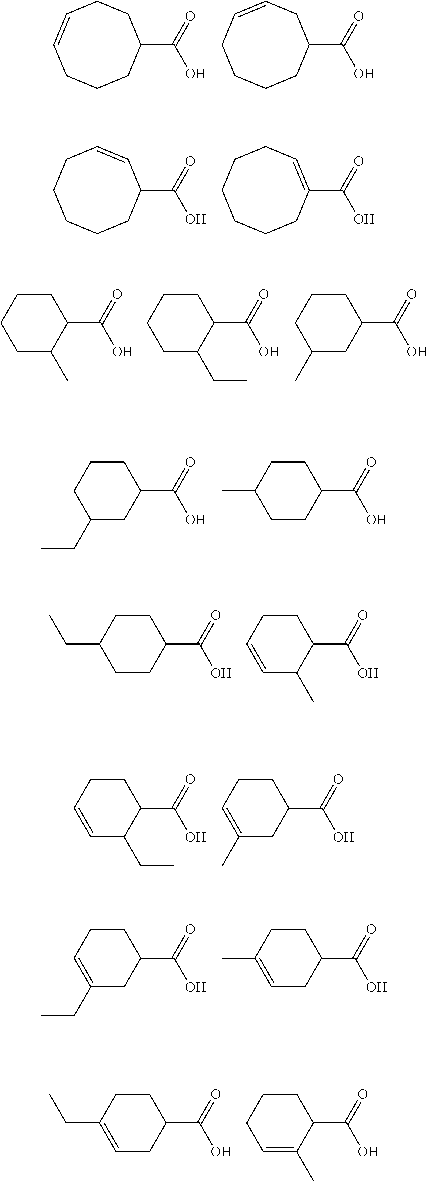

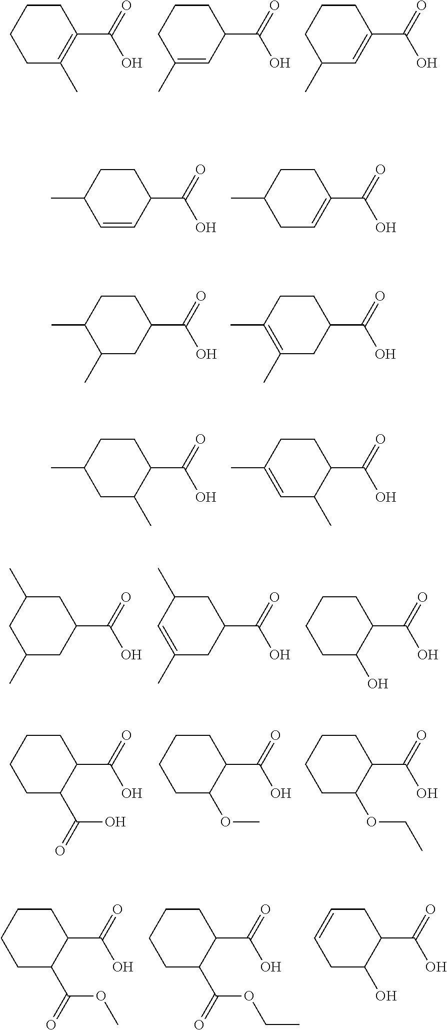

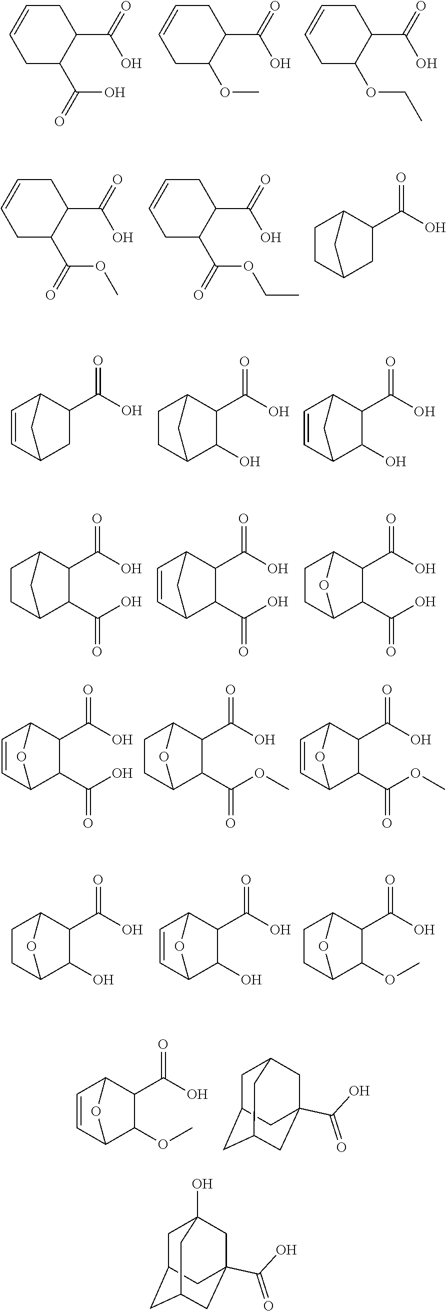

A ratio of the fluorene structure in the polymer containing a fluorene structure is not particularly limited, but a ratio of monomers containing a fluorene structure to all monomers during the production of the polymer containing a fluorene structure is preferably 10% by mol to 90% by mol, more preferably 20% by mol to 80% by mol, and particularly preferably 30% by mol to 70% by mol. Here, as the monomers, for example, in the example of the production methods (i) to (iv), the following compounds correspond to the monomers.
Dihydroxy compound represented by Formula (A1-1)
Diepoxy compound having two epoxy groups
Diepoxy compound represented by Formula (A1-2)
Dicarboxy compound having two carboxy groups
Dihydroxy compound having two hydroxy groups
Monocarboxy compound having one carboxy group

The content of the polymer containing a fluorene structure in the resist underlayer film-forming composition is not particularly limited, and is preferably 30% by mass to 95% by mass, more preferably 50% by mass to 90% by mass, and particularly preferably 60% by mass to 85% by mass, with respect to film constituent components.

The film constituent components are components obtained by removing a volatile component (solvent) from the resist film-forming composition.

### <Crosslinking Agent>

The resist underlayer film-forming composition preferably contains a crosslinking agent from the viewpoint of suitably obtaining the effects of the present invention.

The crosslinking agent contained as an optional component in the resist underlayer film-forming composition has, for example, an inherently reactive functional group.

Examples of the crosslinking agent include hexamethoxymethylmelamine, tetramethoxymethylbenzoguanamine, 1,3,4,6-tetrakis(methoxymethyl)glycoluril(tetramethoxymethyl glycoluril) (POWDERLINK [registered trademark]1174), 1,3,4,6-tetrakis(butoxymethyl)glycoluril, 1,3,4,6-tetrakis(hydroxymethyl)glycoluril, 1,3-bis(hydroxymethyl)urea, 1,1,3,3-tetrakis(butoxymethyl)urea, 1,1,3,3-tetrakis(methoxymethyl)urea, and other crosslinking agents.

In addition, the crosslinking agent may be a nitrogen-containing compound having 2 to 6 substituents in one molecule, each being represented by Formula (1d) and bonded to a nitrogen atom, which is described in WO 2017/187969 A.

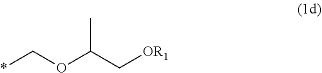

(In Formula (1d), R₁ represents a methyl group or an ethyl group, and * represents a bond bonded to a nitrogen atom.)

The nitrogen-containing compound having 2 to 6 substituents in one molecule, each being represented by Formula (1d), may be a glycoluril derivative represented by Formula (1E).

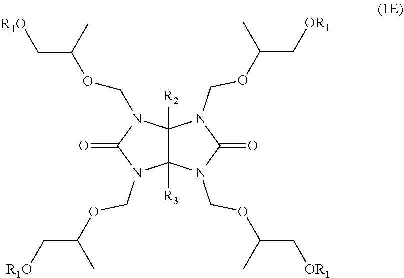

(In Formula (1E), four R₁'s each independently represent a methyl group or an ethyl group, and R₂ and R₃ each independently represent a hydrogen atom, an alkyl group having 1 to 4 carbon atoms, or a phenyl group.)

Examples of the glycoluril derivative represented by Formula (1E) include compounds represented by Formulae (1E-1) to (1E-6).

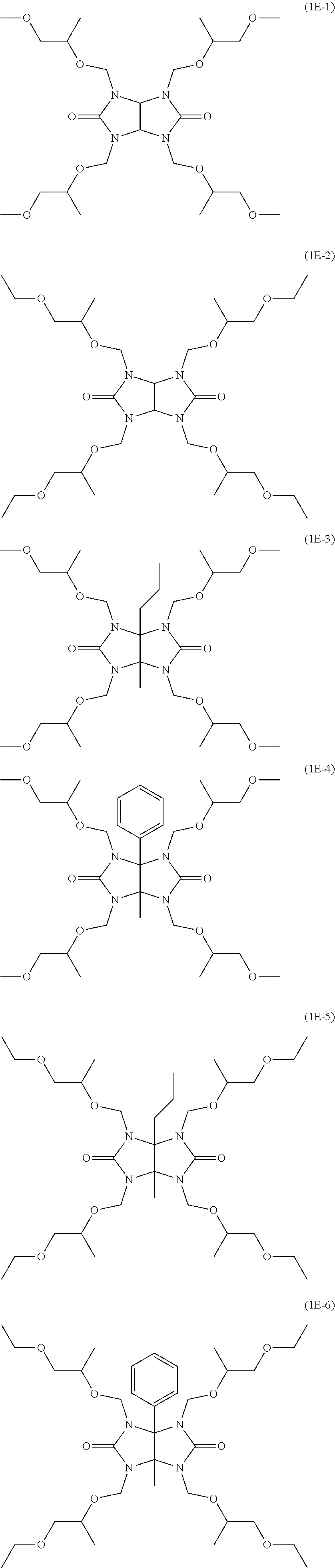

The nitrogen-containing compound having 2 to 6 substituents in one molecule, each being represented by Formula (1d), is obtained by the reaction of a nitrogen-containing compound having 2 to 6 substituents in one molecule, each being represented by Formula (2d) and bonded to a nitrogen atom, with at least one compound represented by Formula (3d).

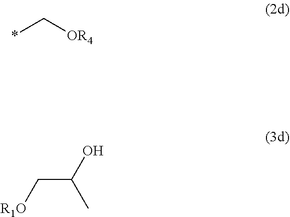

(In Formula (2d) and Formula (3d), R₁ represents a methyl group or an ethyl group, and R₄ represents an alkyl group having 1 to 4 carbon atoms, and * represents a bond bonded to a nitrogen atom.)

The glycoluril derivative represented by Formula (1E) is obtained by the reaction of a glycoluril derivative represented by Formula (2E) with at least one compound represented by Formula (3d).

The nitrogen-containing compound having 2 to 6 substituents in one molecule, each being represented by Formula (2d), is a glycoluril derivative represented by Formula (2E).

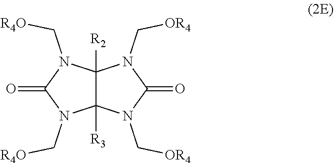

(In Formula (2E), R₂ and R₃ each independently represent a hydrogen atom, an alkyl group having 1 to 4 carbon atoms, or a phenyl group, and R₄'s each independently represent an alkyl group having 1 to 4 carbon atoms.)

Examples of the glycoluril derivative represented by Formula (2E) include compounds represented by Formulae (2E-1) to (2E-4). Examples of the compound represented by Formula (3d) further include compounds represented by Formulae (3d-1) and (3d-2).

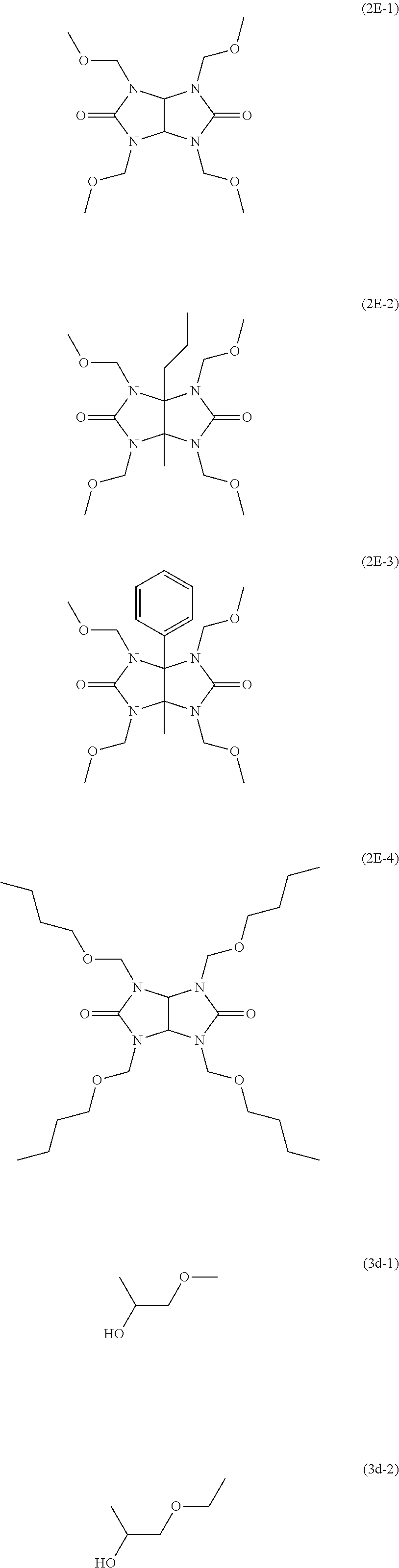

For the content related to the nitrogen-containing compound having 2 to 6 substituents in one molecule, each being represented by Formula (1d) and bonded to a nitrogen atom, the entire disclosure of WO 2017/187969 A is incorporated in the present application.

The above-described crosslinking agent may be a crosslinkable compound represented by Formula (G-1) or (G-2) described in WO 2014/208542 A.

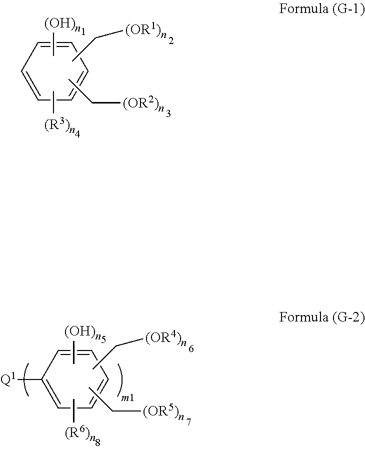

(In the formula, Q¹ represents a single bond or an m1-valent organic group, R¹ and R⁴ each represent an alkyl group having 2 to 10 carbon atoms or an alkyl group having 2 to 10 carbon atoms having an alkoxy group having 1 to 10 carbon atoms, R² and R⁵ each represent a hydrogen atom or a methyl group, and R³ and R⁶ each represent an alkyl group having 1 to 10 carbon atoms or an aryl group having 6 to 40 carbon atoms,
n1 represents an integer of 1≤n1≤3, n2 represents an integer of 2≤n2≤5, n3 represents an integer of 0≤n3≤3, n4 represents an integer of 0≤n4≤3, and an integer of 3≤(n1+n2+n3+n4)≤6,
n5 represents an integer of 1≤n5≤3, n6 represents an integer of 1≤n6≤4, n7 represents an integer of 0≤n7≤3, n8 represents an integer of 0≤n8≤3, and an integer of 2≤(n5+n6+n7+n8)≤5, and m1 represents an integer of 2 to 10.)

The crosslinkable compound represented by Formula (G-1) or (G-2) may be obtained by the reaction of a compound represented by Formula (G-3) or (G-4) with a hydroxyl group-containing ether compound or an alcohol having 2 to 10 carbon atoms.

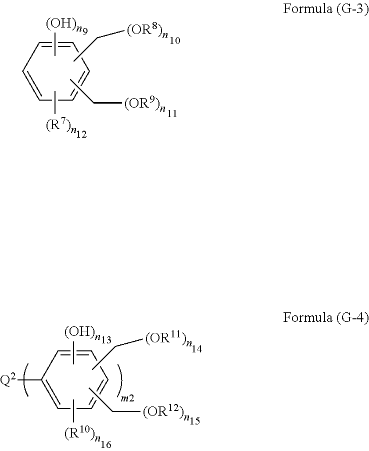

(In the formula, Q₂ represents a single bond or an m2-valent organic group, R⁸, R⁹, R¹¹, and R¹² each represent a hydrogen atom or a methyl group, and R⁷ and R¹⁰ each represent an alkyl group having 1 to 10 carbon atoms or an aryl group having 6 to 40 carbon atoms,
n9 represents an integer of 1≤n9≤3, n10 represents an integer of 2≤n10≤5, n11 represents an integer of 0≤n11≤3, n12 represents an integer of 0≤n12≤3, and an integer of 3≤(n9+n10+n11+n12)≤6,
n13 represents an integer of 1≤n13≤3, n14 represents an integer of 1≤n14≤4, n15 represents an integer of 0≤n15≤3, n16 represents an integer of 0≤n16≤3, and an integer of 2≤(n13+n14+n15+n16)≤5, and
m2 represents an integer of 2 to 10.)

The compounds represented by Formula (G-1) and Formula (G-2) can be, for example, exemplified below.

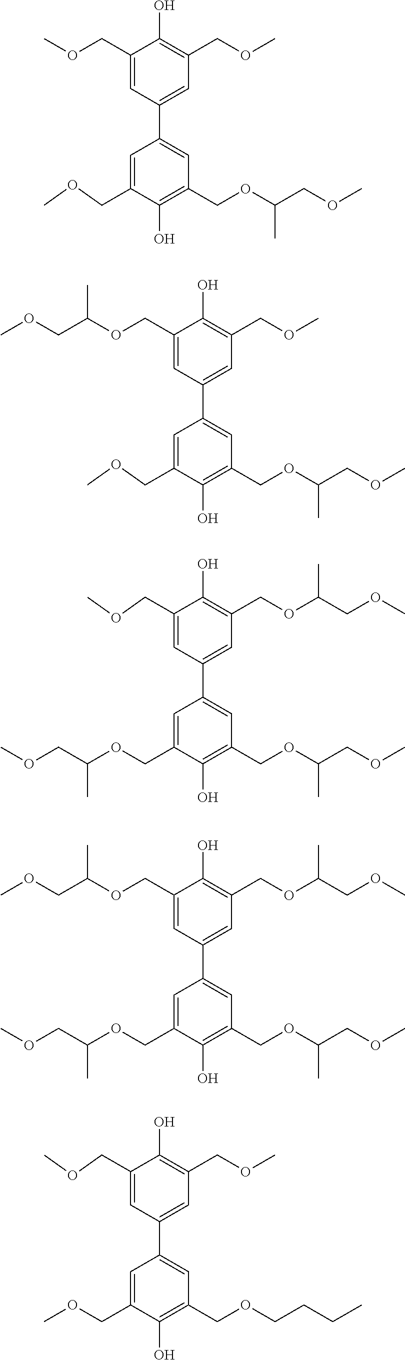

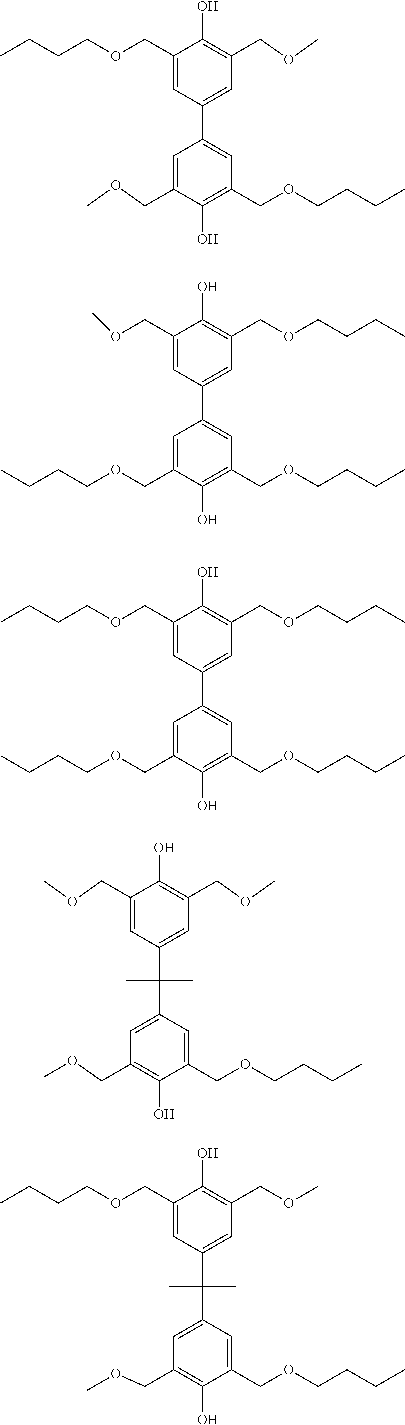

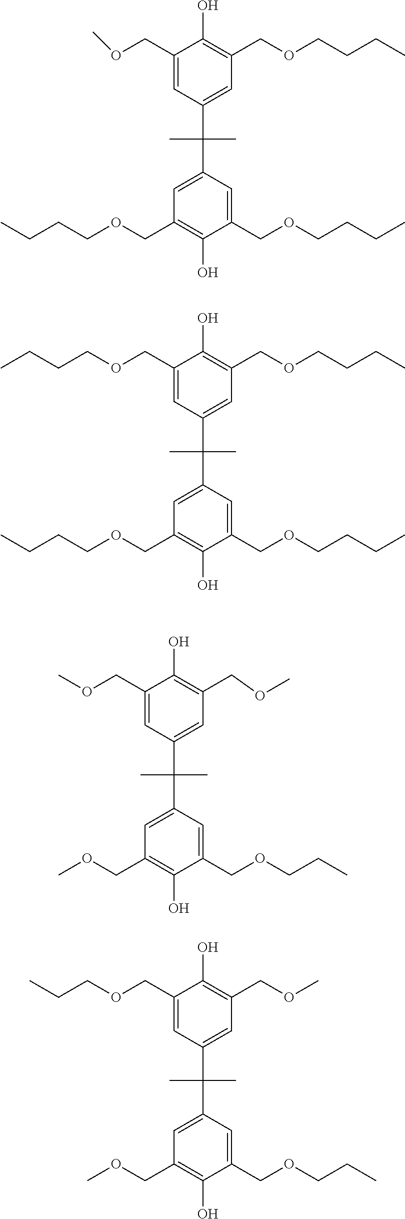

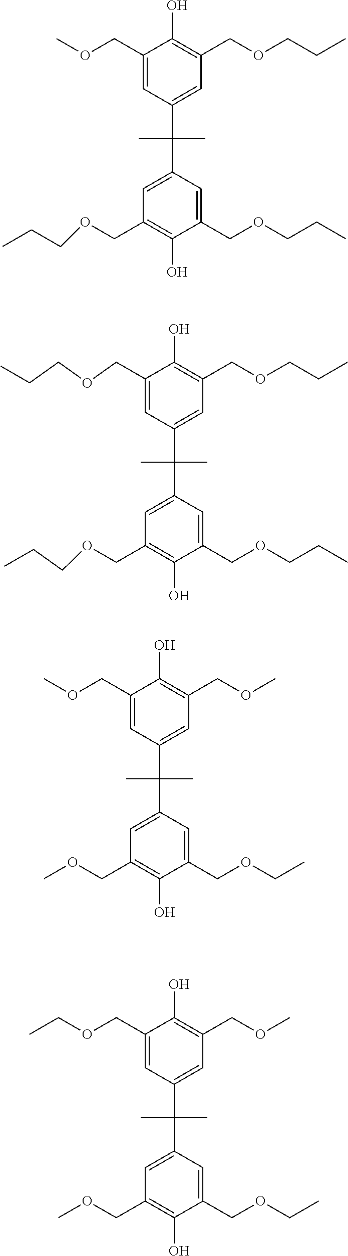

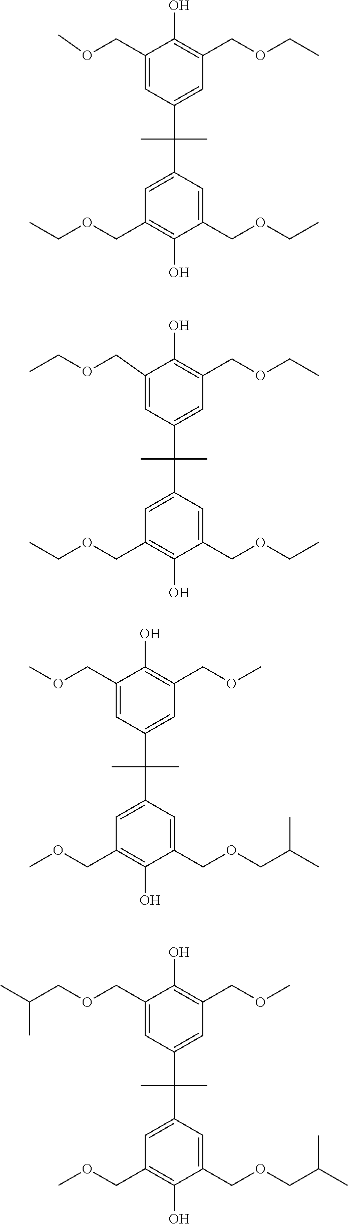

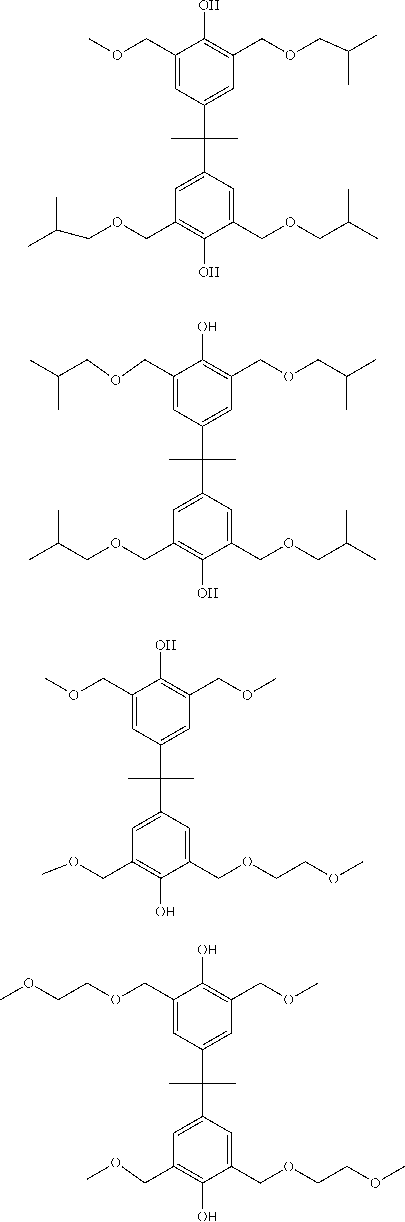

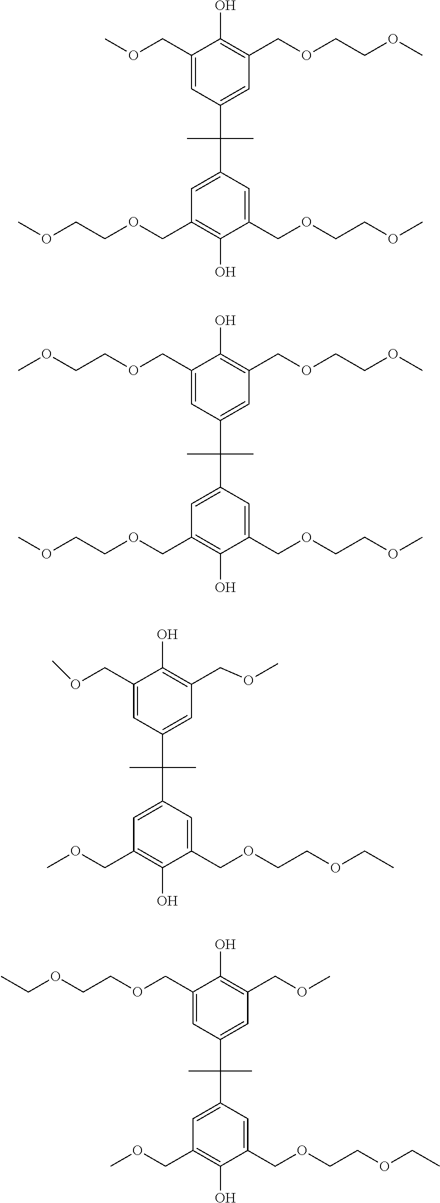

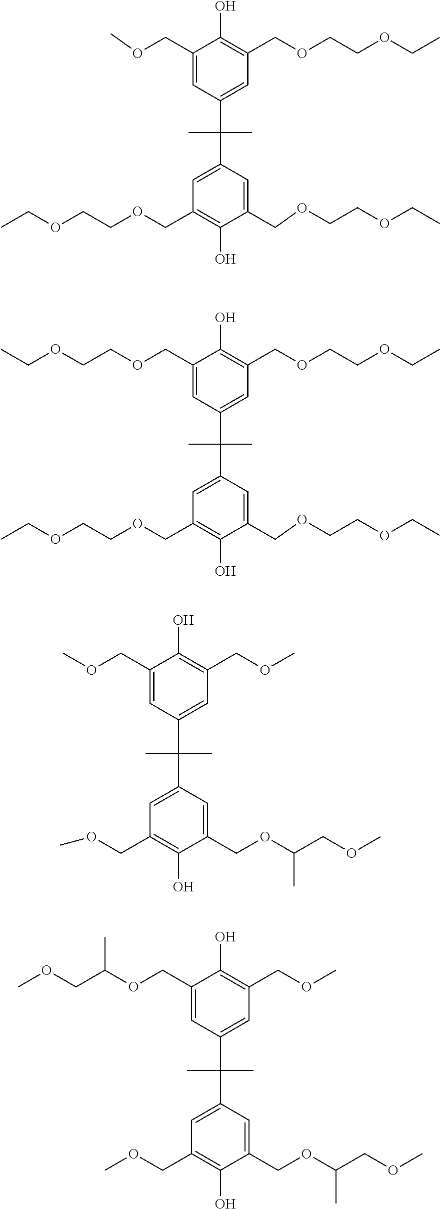

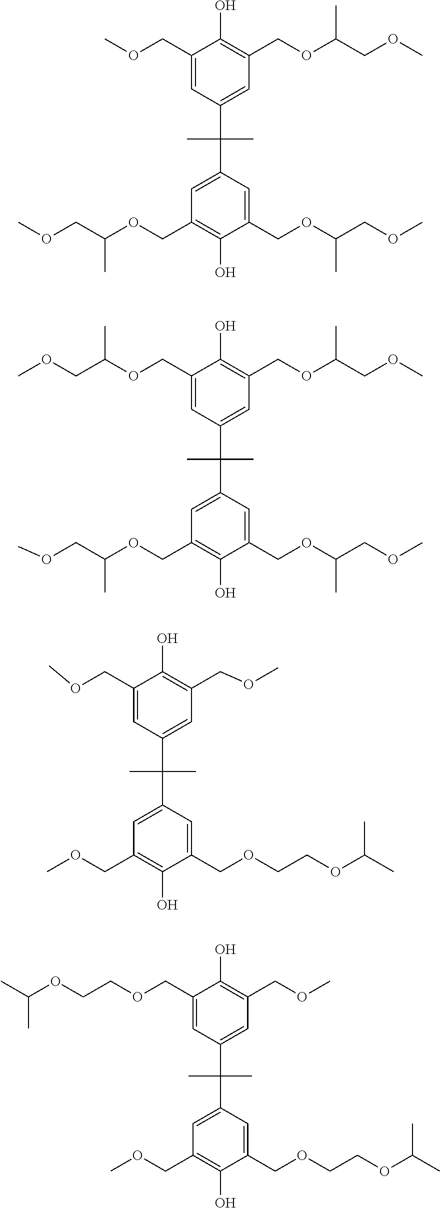

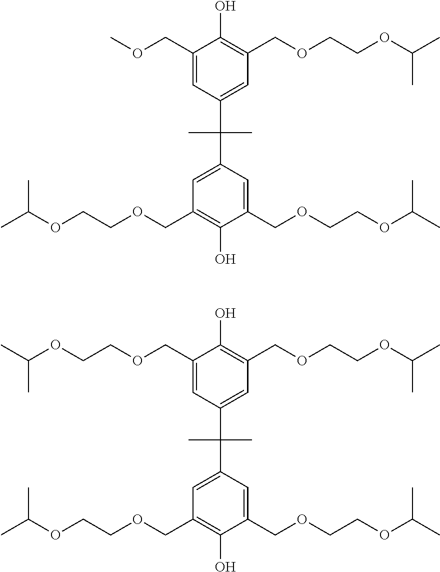

The compounds represented by Formula (G-3) and Formula (G-4) can be, for example, exemplified below.

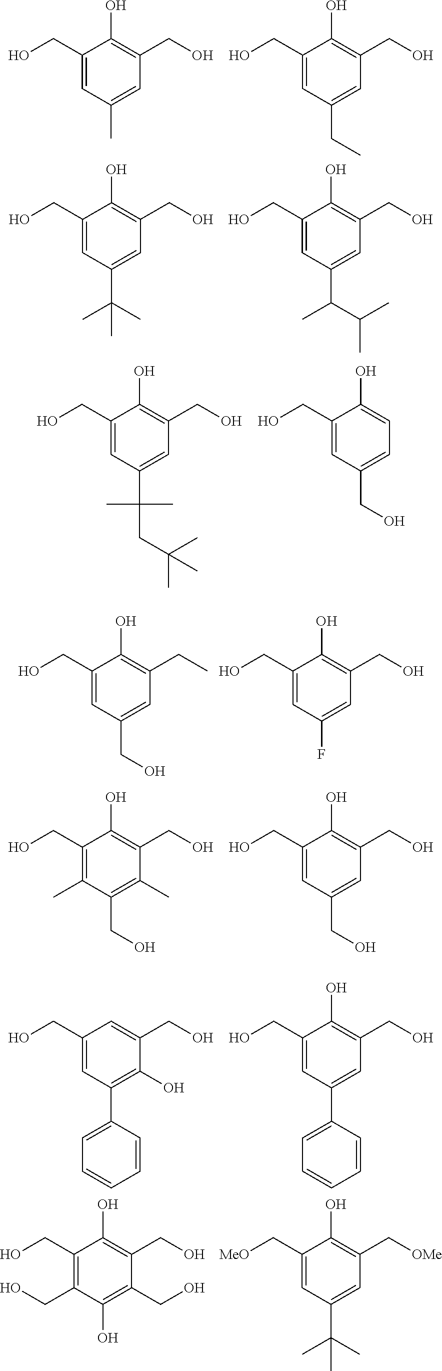

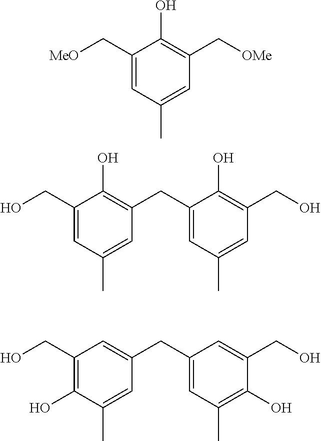

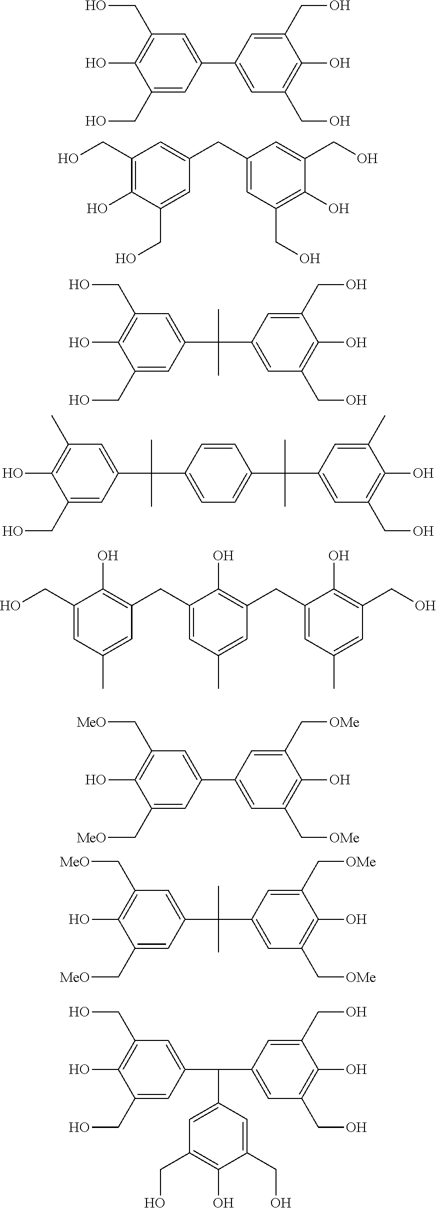

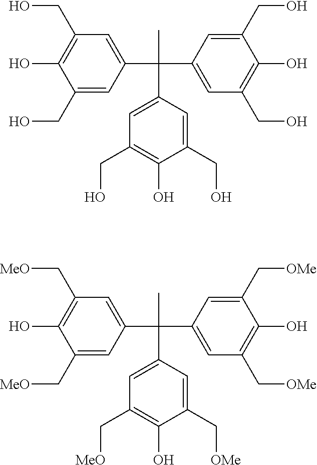

In the formula, Me represents a methyl group.

The entire disclosure of WO 2014/208542 A is incorporated herein by reference.

In a case where the crosslinking agent is used, the content ratio of the crosslinking agent in the resist underlayer film-forming composition is, for example, 1% by mass to 50% by mass, preferably 5% by mass to 40% by mass, with respect to the polymer containing a fluorene structure.

### <Curing Catalyst>

As the curing catalyst contained as an optional component in the resist underlayer film-forming composition, both a thermal acid generator and a photoacid generator can be used, but it is preferable to use a thermal acid generator.

Examples of the thermal acid generator include sulfonic acid compounds and carboxylic acid compounds, such as p-toluenesulfonic acid, trifluoromethanesulfonic acid, pyridinium-p-toluenesulfonate (pyridinium-p-toluenesulfonic acid), pyridinium phenolsulfonic acid, pyridinium-p-hydroxybenzenesulfonic acid (pyridinium p-phenolsulfonic acid salt), pyridinium-trifluoromethanesulfonic acid, salicylic acid, camphorsulfonic acid, 5-sulfosalicylic acid, 4-chlorobenzenesulfonic acid, 4-hydroxybenzenesulfonic acid, benzenedisulfonic acid, 1-naphthalenesulfonic acid, citric acid, benzoic acid, and hydroxybenzoic acid.

Examples of the photoacid generator include an onium salt compound, a sulfonimide compound, a disulfonyldiazomethane compound, and other photoacid generators.

Examples of the onium salt compound include iodonium salt compounds such as diphenyliodonium hexafluorophosphate, diphenyliodonium trifluoromethanesulfonate, diphenyliodonium nonafluoronormalbutanesulfonate, diphenyliodonium perfluoronormaloctanesulfonate, diphenyliodonium camphorsulfonate, bis(4-tert-butylphenyl)iodonium camphorsulfonate, and bis(4-tert-butylphenyl)iodonium trifluoromethanesulfonate, and sulfonium salt compounds such as triphenylsulfonium hexafluoroantimonate, triphenylsulfonium nonafluoronormalbutanesulfonate, triphenylsulfonium camphorsulfonate, and triphenylsulfonium trifluoromethanesulfonate.

Examples of the sulfonimide compound include N-(trifluoromethanesulfonyloxy)succinimide, N-(nonafluoronormalbutanesulfonyloxy)succinimide, N-(camphorsulfonyloxy)succinimide, N-(trifluoromethanesulfonyloxy)naphthalimide, and other sulfonimide compounds.

Examples of the disulfonyl diazomethane compound include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, methylsulfonyl-p-toluenesulfonyl diazomethane, and other disulfonyl diazomethane compounds.

Only one kind of curing catalyst can be used alone, or two or more kinds thereof can be used in combination.

In a case where the curing catalyst is used, the content ratio of the curing catalyst is, for example, 0.1% by mass to 50% by mass, and preferably 1% by mass to 30% by mass, with respect to the crosslinking agent.

### <Solvent>

As the solvent, an organic solvent generally used for a chemical solution in a semiconductor lithography step is preferable. Specific examples thereof include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propylene glycol propyl ether acetate, toluene, xylene, methyl ethyl ketone, methyl isobutyl ketone, cyclopentanone, cyclohexanone, cycloheptanone, 4-methyl-2-pentanol, methyl 2-hydroxyisobutyrate, ethyl 2-hydroxyisobutyrate, ethyl ethoxyacetate, 2-hydroxyethyl acetate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, 2-heptanone, methoxycyclopentane, anisole, γ-butyrolactone, N-methylpyrrolidone, N,N-dimethylformamide, and N,N-dimethylacetamide. These solvents can be used alone or in combination of two or more kinds thereof.

Among these solvents, propylene glycol monomethyl ether, propylene glycol monomethyl ether acetate, ethyl lactate, butyl lactate, and cyclohexanone are preferable. In particular, propylene glycol monomethyl ether and propylene glycol monomethyl ether acetate are preferable.

### <Other Components>

A surfactant can be further added to the resist underlayer film-forming composition in order to reduce the occurrence of pinholes, striations, or defect sites, and further to improve the coatability with respect to surface unevenness.

Examples of the surfactant include nonionic surfactants such as polyoxyethylene alkyl ethers such as polyoxyethylene lauryl ether, polyoxyethylene stearyl ether, polyoxyethylene cetyl ether, and polyoxyethylene oleyl ether, polyoxyethylene alkylaryl ethers such as polyoxyethylene octylphenol ether and polyoxyethylene nonylphenol ether, polyoxyethylene-polyoxypropylene block copolymers, sorbitan fatty acid esters such as sorbitan monolaurate, sorbitan monopalmitate, sorbitan monostearate, sorbitan monooleate, sorbitan trioleate, and sorbitan tristearate, polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate, F-TOP EF301, EF303, EF352 (manufactured by Tochem Co., Ltd., trade name), fluorine-based surfactants such as MEGAFACE F171, F173, R-30 (manufactured by DIC Corporation, trade name), Fluorad FC430 and FC431 (manufactured by Sumitomo 3M Ltd., trade name), AsahiGuard AG710, Surflon S-382, SC101, SC102, SC103, SC104, SC105, and SC106 (manufactured by Asahi Glass Co., Ltd., trade name), and organosiloxane polymer KP341 (manufactured by Shin-Etsu Chemical Co., Ltd.).

The blending amount of these surfactants is not particularly limited, and is usually 2.0% by mass or less, and preferably 1.0% by mass or less with respect to the total solid content of the resist underlayer film-forming composition.

These surfactants may be added alone, or two or more kinds thereof may be added in combination.

The film constituent components contained in the resist underlayer film-forming composition, that is, the components excluding the solvent are, for example, 0.01% by mass to 10% by mass of the resist underlayer film-forming composition.

The resist underlayer film-forming composition for EB or EUV lithography is preferably used to form a resist underlayer film for EB or EUV lithography, the resist underlayer film having a film thickness of 10 nm or less.

### (Resist Underlayer Film for EB or EUV Lithography)

The resist underlayer film for EB or EUV lithography (hereinafter, simply referred to as the “resist underlayer film” in some cases) of the present invention is a cured product formed from the resist underlayer film-forming composition for EB or EUV lithography described above.

The resist underlayer film can be produced, for example, by applying the resist underlayer film-forming composition for EB or EUV lithography described above onto a semiconductor substrate and baking the resist underlayer film-forming composition.

Examples of the semiconductor substrate to which the resist underlayer film-forming composition is applied include silicon wafers, germanium wafers, and compound semiconductor wafers such as gallium arsenide, indium phosphide, gallium nitride, indium nitride, and aluminum nitride.

In a case where a semiconductor substrate having a surface on which an inorganic film is formed is used, the inorganic film is formed by, for example, an atomic layer deposition (ALD) method, a chemical vapor deposition (CVD) method, a reactive sputtering method, an ion plating method, a vacuum deposition method, or a spin coating method (spin on glass, SOG). Examples of the inorganic film include a polysilicon film, a silicon oxide film, a silicon nitride film, a boro-phospho silicate glass (BPSG) film, a titanium nitride film, a titanium nitride oxide film, a tungsten film, a gallium nitride film, and a gallium arsenide film.

The resist underlayer film-forming composition of the present invention is applied onto such a semiconductor substrate by an appropriate application method such as a spinner or a coater. Thereafter, the resist underlayer film is formed by baking using heating means such as a hot plate. Baking conditions are appropriately selected from a baking temperature of 100° C. to 400° C. and a baking time of 0.3 minutes to 60 minutes. The baking temperature is preferably 120° C. to 350° C. and the baking time is preferably 0.5 minutes to 30 minutes, and the baking temperature is more preferably 150° C. to 300° C., and the baking time is more preferably 0.8 minutes to 10 minutes.

The film thickness of the resist underlayer film is, for example, 0.001 μm (1 nm) to 10 μm, 0.002 μm (2 nm) to 1 μm, 0.005 μm (5 nm) to 0.5 μm (500 nm), 0.001 μm (1 nm) to 0.05 μm (50 nm), 0.002 μm (2 nm) to 0.05 μm (50 nm), 0.003 μm (3 nm) to 0.05 μm (50 nm), 0.004 μm (4 nm) to 0.05 μm (50 nm), 0.005 μm (5 nm) to 0.05 μm (50 nm), 0.003 μm (3 nm) to 0.03 μm (30 nm), 0.003 μm (3 nm) to 0.02 μm (20 nm), 0.005 μm (5 nm) to 0.02 μm (20 nm), 0.005 μm (5 nm) to 0.02 μm (20 nm), 0.003 μm (3 nm) to 0.01 μm (10 nm), 0.005 μm (5 nm) to 0.01 μm (10 nm), 0.003 μm (3 nm) to 0.006 μm (6 nm), or 0.005 μm (5 nm).

The method for measuring a film thickness of the resist underlayer film in the present specification is as follows.
Measuring apparatus name: Ellipso type film thickness measuring apparatus RE-3100 (SCREEN Holdings Co., Ltd.)
Single wavelength ellipsometer (SWE) mode
Arithmetic average of 8 points (for example, 8 points are measured at intervals of 1 cm in X direction of wafer)

### (Semiconductor Processing Substrate)

A semiconductor processing substrate of the present invention is provided with a semiconductor substrate and the resist underlayer film for EB or EUV lithography of the present invention.

Examples of the semiconductor substrate include the above-described semiconductor substrate.

The resist underlayer film is disposed on the semiconductor substrate, for example.

### (Method for Manufacturing Semiconductor Element and Method for Forming Pattern)

A method for manufacturing a semiconductor element of the present invention includes at least steps as follows:
a step of forming a resist underlayer film on a semiconductor substrate by using the resist underlayer film-forming composition for EB or EUV lithography of the present invention; and
a step of forming a resist film on the resist underlayer film.

The method for forming a pattern of the present invention includes at least steps as follows:
a step of forming a resist underlayer film on a semiconductor substrate by using the resist underlayer film-forming composition for EB or EUV lithography of the present invention;
a step of forming a resist film on the resist underlayer film;
a step of irradiating the resist film with EB or EUV and developing the resist film to obtain a resist pattern;
and a step of etching the resist underlayer film by using the resist pattern as a mask.

Usually, the resist film is formed on the resist underlayer film.

The film thickness of the resist film is preferably 200 nm or less, more preferably 150 nm or less, still more preferably 100 nm or less, and particularly preferably 80 nm or less. The film thickness of the resist film is preferably 10 nm or more, more preferably 20 nm or more, and particularly preferably 30 nm or more.

A method for forming the resist film is not particularly limited.

The resist film formed on the resist underlayer film by, for example, coating and baking with a known method is not particularly limited as long as it responds to EB or EUV used for irradiation. Both a negative photoresist and a positive photoresist can be used.

In the present specification, a resist responding to EB is also referred to as a photoresist.

Examples of the photoresist include a positive photoresist containing a novolac resin and 1,2-naphthoquinonediazide sulfonate ester; a chemically amplified photoresist containing a binder having a group elevating an alkali dissolving rate by being decomposed by an acid, and a photoacid generator; a chemically amplified photoresist containing a low molecule compound elevating an alkali dissolving rate of a photoresist by being decomposed by an acid, an alkali-soluble binder, and a photoacid generator; and a chemically amplified photoresist containing a binder having a group elevating an alkali dissolving rate by being decomposed by an acid, a low molecule compound elevating an alkali dissolving rate of a photoresist by being decomposed by an acid, and a photoacid generator. Examples thereof include V146G (trade name) manufactured by JSR Corporation, APEX-E (trade name) manufactured by Shipley Company L.L.C., PAR710 (trade name) manufactured by Sumitomo Chemical Co., Ltd., and AR2772 and SEPR430 (trade names) manufactured by Shin-Etsu Chemical Co., Ltd. Furthermore, examples thereof include fluorine-containing atomic polymer-based photoresists as described in Proc. SPIE, Vol. 3999, 330-334 (2000), Proc. SPIE, Vol. 3999, 357-364 (2000), and Proc. SPIE, Vol. 3999, 365-374 (2000).

So-called resist compositions such as resist compositions, radiation-sensitive resin compositions, high-resolution patterning compositions based on organometallic solutions, and metal-containing resist compositions described in WO 2019/188595 A, WO 2019/187881 A, WO 2019/187803 A, WO 2019/167737 A, WO 2019/167725 A, WO 2019/187445 A, WO 2019/167419 A, WO 2019/123842 A, WO 2019/054282 A, WO 2019/058945 A, WO 2019/058890 A, WO 2019/039290 A, WO 2019/044259 A, WO 2019/044231 A, WO 2019/026549 A, WO 2018/193954 A, WO 2019/172054 A, WO 2019/021975, WO 2018/230334 A, WO 2018/194123 A, JP 2018-180525 A, WO 2018/190088 A, JP 2018-070596 A, JP 2018-028090 A, JP 2016-153409 A, JP 2016-130240 A, JP 2016-108325 A, JP 2016-047920 A, JP 2016-035570 A, JP 2016-035567 A, JP 2016-035565 A, JP 2019-101417 A, JP 2019-117373 A, JP 2019-052294 A, JP 2019-008280 A, JP 2019-008279 A, JP 2019-003176 A, JP 2019-003175 A, JP 2018-197853 A, JP 2019-191298 A, JP 2019-061217 A, JP 2018-045152 A, JP 2018-022039 A, JP 2016-090441 A, JP 2015-10878 A, JP 2012-168279 A, JP 2012-022261 A, JP 2012-022258 A, JP 2011-043749 A, JP 2010-181857 A, JP 2010-128369 A, WO 2018/031896 A, JP 2019-113855 A, WO 2017/156388 A, WO 2017/066319 A, JP 2018-41099 A, WO 2016/065120 A, WO 2015/026482 A, JP 2016-29498 A, JP 2011-253185 A can be used, but are not limited thereto.

Examples of the resist composition include the following compositions.

An actinic ray-sensitive or radiation-sensitive resin composition containing: a resin A that has a repeating unit having an acid-decomposable group in which a polar group is protected with a protective group removable by the action of an acid, and a compound represented by General Formula (21),

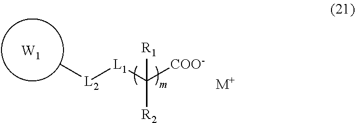

where in Formula (21), m represents an integer of 1 to 6,
R₁ and R² each independently represent a fluorine atom or a perfluoroalkyl group,
L₁ represents —O—, —S—, —COO—, —SO₂—, or —SO₃—,
L₂ represents an alkylene group, which may have a substituent, or a single bond,
W₁ represents a cyclic organic group, which may have a substituent, and
M⁺ represents a cation.

A metal-containing film-forming composition for lithography with an extreme ultraviolet ray or electron beam, containing: a compound that has a metal-oxygen covalent bond; and a solvent, in which a metal element in the compound belongs to period 3 to period 7 of group 3 to group 15 in periodic table.

A radiation-sensitive resin composition containing: a polymer having a first structural unit represented by Formula (31) and a second structural unit represented by Formula (32) and having an acid-dissociable group; and an acid generator,

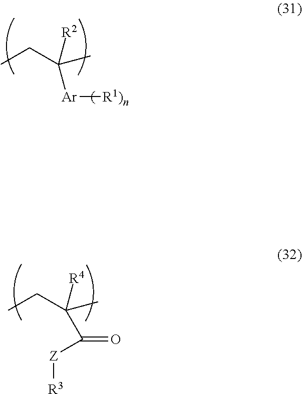

(where in Formula (31), Ar is a group obtained by removing (n+1) hydrogen atoms from arene having 6 to 20 carbon atoms, R¹ is a hydroxy group, a sulfanyl group, or a monovalent organic group having 1 to 20 carbon atoms, n is an integer of 0 to 11, in a case where n is 2 or more, a plurality of R's are the same as or different from one another, R² is a hydrogen atom, a fluorine atom, a methyl group, or a trifluoromethyl group, where in Formula (32), R³ is a monovalent group having 1 to 20 carbon atoms and containing the acid-dissociable group, Z is a single bond, an oxygen atom, or a sulfur atom, and R⁴ is a hydrogen atom, a fluorine atom, a methyl group, or a trifluoromethyl group).

A resist composition containing: a resin (A₁) that has a structural unit having a cyclic carbonate structure, a structural unit represented by a formula described below, and a structural unit having an acid-unstable group; and an acid generator,

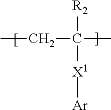

[where,
R² represents an alkyl group having 1 to 6 carbon atoms, which may have a halogen atom, a hydrogen atom, or a halogen atom, X¹ represents a single bond, —CO—O—*, or —CO—NR⁴—*, * represents a bond with —Ar, R⁴ represents a hydrogen atom or an alkyl group having 1 to 4 carbon atoms, and Ar represents an aromatic hydrocarbon group having 6 to 20 carbon atoms, which may have one or more groups selected from the group consisting of a hydroxy group and a carboxyl group].

Examples of the resist film include the following.

A resist film containing a base resin that has a repeating unit represented by Formula (a1) and/or a repeating unit represented by Formula (a2), and a repeating unit generating, by exposure, an acid bonded to a polymer main chain,

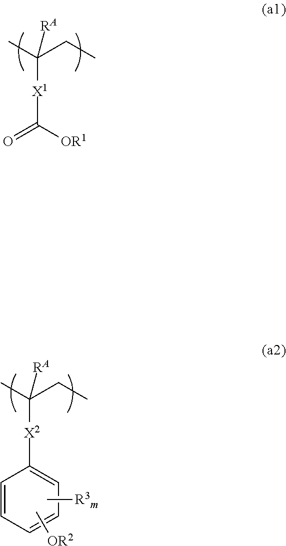

(where in Formula (a1) and Formula (a2), R^{A}'s are each independently a hydrogen atom or a methyl group, R¹ and R² are each independently a tertiary alkyl group having 4 to 6 carbon atoms, R³'s each independently represent a fluorine atom or a methyl group, m is an integer of 0 to 4, X¹ is a single bond, a phenylene group or a naphthylene group, or a linking group having 1 to 12 carbon atoms, which contains at least one selected from an ester bond, a lactone ring, a phenylene group, and a naphthylene group, and X² is a single bond, an ester bond, or an amide bond).

Examples of the resist material include the following.

A resist material containing a polymer that has a repeating unit represented by Formula (b1) or Formula (b2),

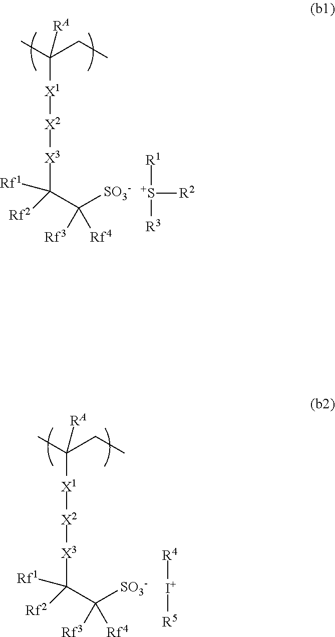

(where in Formula (b1) and Formula (b2), R^{A}'s are each independently a hydrogen atom or a methyl group, X¹ is a single bond or an ester group, X² is a linear, branched, or cyclic alkylene group having 1 to 12 carbon atoms or an arylene group having 6 to 10 carbon atoms, and a part of a methylene group constituting the alkylene group may be substituted with an ether group, an ester group, or a lactone ring-containing group, and at least one hydrogen atom contained in X² is substituted with a bromine atom, X³ is a single bond, an ether group, an ester group, or a linear, branched, or cyclic alkylene group having 1 to 12 carbon atoms, and a part of a methylene group constituting the alkylene group may be substituted with an ether group or an ester group, Rf¹ to Rf⁴ are each independently a hydrogen atom, a fluorine atom, or a trifluoromethyl group, and at least one of Rf¹ to Rf⁴ is a fluorine atom or a trifluoromethyl group, Rf¹ and Rf² may also be combined to form a carbonyl group, R¹ to R⁵ are each independently a linear, branched, or cyclic alkyl group having 1 to 12 carbon atoms, a linear, branched, or cyclic alkenyl group having 2 to 12 carbon atoms, an alkynyl group having 2 to 12 carbon atoms, an aryl group having 6 to 20 carbon atoms, an aralkyl group having 7 to 12 carbon atoms, or an aryloxyalkyl group having 7 to 12 carbon atoms, some or all of hydrogen atoms of these groups may be substituted with a hydroxy group, a carboxy group, a halogen atom, an oxo group, a cyano group, an amide group, a nitro group, a sultone group, a sulfone group, or a sulfonium salt-containing group, and some of methylene groups constituting these groups may be substituted with an ether group, an ester group, a carbonyl group, a carbonate group, or a sulfonic acid ester group, and R¹ and R² may also be bonded to each other to form a ring together with the sulfur atom to which R¹ and R² are bonded).

A resist material containing a base resin that contains a polymer having a repeating unit represented by Formula (a),

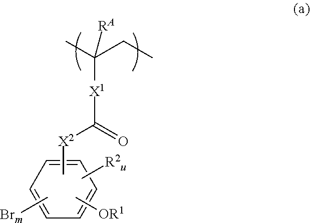

(where in Formula (a), R^{A} is a hydrogen atom or a methyl group, R¹ is a hydrogen atom or an acid-unstable group, R² is a linear, branched, or cyclic alkyl group having 1 to 6 carbon atoms or a halogen atom other than bromine, X¹ is a single bond or a phenylene group, or a linear, branched, or cyclic alkylene group having 1 to 12 carbon atoms, which may have an ester group or a lactone ring, X₂ is —O—, —O—CH₂—, or —NH—, m is an integer of 1 to 4, and u is an integer of 0 to 3, where, m+u is an integer of 1 to 4).

A resist composition generating an acid by exposure and having solubility in a developer changed by an action of an acid, the resist composition containing a base material component (A) that has a solubility in a developer changed by an action of an acid, and a fluorine additive component (F) that exhibits decomposability in an alkaline developer, in which the fluorine additive component (F) contains a fluororesin component (F1) that has a constituent unit (f1) containing a base-dissociable group and a constituent unit (f2) containing a group represented by General Formula (f2-r-1),

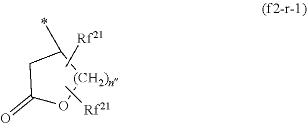

[where in Formula (f2-r-1), Rf²¹'s each independently represents a hydrogen atom, an alkyl group, an alkoxy group, a hydroxyl group, a hydroxyalkyl group, or a cyano group, n″ is an integer of 0 to 2, and * is a bond].

The constituent unit (f1) includes a constituent unit represented by General Formula (f1-1) or a constituent unit represented by General Formula (f1-2),

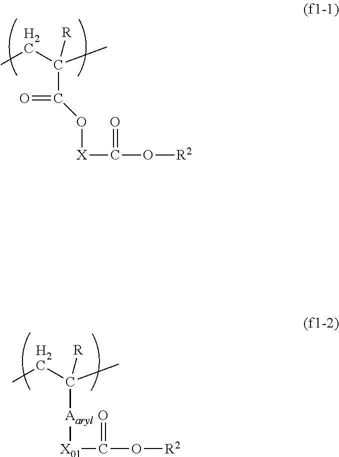

[where in Formulae (f1-1) and (f1-2), R's each independently represent a hydrogen atom, an alkyl group having 1 to 5 carbon atoms, or a halogenated alkyl group having 1 to 5 carbon atoms, X is a divalent linking group having no acid-dissociable moiety, A_{aryl} is a divalent aromatic cyclic group, which may have a substituent, X₀₁ is a single bond or a divalent linking group, and R²'s are each independently an organic group having a fluorine atom].

Examples of a coating, a coating solution, and a coating composition include the followings.

A coating including a metal oxo-hydroxo network having organic ligands via a metal carbon bond and/or a metal carboxylate bond.

An inorganic oxo/hydroxo-based composition.

A coating solution containing:
an organic solvent; and
a first organometallic composition represented by Formula R_{z}SnO_{(2-(z/2)-(x/2))} (OH)ₓ, where 0<z≤2 and 0<(z+x)≤4, by Formula R′SnX₄₋ₙ, where n=1 or 2, or a mixture thereof, in which R and R′ are independently hydrocarbyl groups having 1 to 31 carbon atoms, and X is a ligand having a hydrolysable bond to Sn or a combination thereof; and
a hydrolysable metal compound represented by Formula MX′ᵥ, where M is a metal selected from groups 2 to 16 in periodic table of elements, v=a number from 2 to 6, and X′ is a ligand having a hydrolysable M-X bond or a combination thereof.

A coating solution containing: an organic solvent; and a first organometallic compound represented by Formula RSnO_{(3/2-x/2)}(OH)ₓ, where 0<x<3, with from about 0.0025 M to about 1.5 M tin in the solution, where R is an alkyl group having 3 to 31 carbon atoms or a cycloalkyl group, and the alkyl group or cycloalkyl group is bonded to the tin at a secondary or tertiary carbon atom.

An aqueous inorganic patterning precursor solution containing a mixture of water, metal suboxide cations, polyatomic inorganic anions, and radiation-sensitive ligands having a peroxide group.

The irradiation with EB or EUV is performed, for example, through a mask (reticle) for forming a predetermined pattern. The resist underlayer film-forming composition of the present invention is applied for electron beam (EB) irradiation or extreme ultraviolet (EUV: 13.5 nm) irradiation, but is preferably applied for extreme ultraviolet (EUV) exposure.

The irradiation energy of EB and the exposure amount of EUV are not particularly limited.

Post exposure bake (PEB) may be performed after irradiation with EB or EUV and before development.

The baking temperature is not particularly limited, but is preferably 60° C. to 150° C., more preferably 70° C. to 120° C., and particularly preferably 75° C. to 110° C.

The baking time is not particularly limited, but is preferably 1 second to 10 minutes, more preferably 10 seconds to 5 minutes, and particularly preferably 30 seconds to 3 minutes.

For the development, for example, an alkaline developer is used.

The development temperature is, for example, 5° C. to 50° C.

The development time is, for example, 10 seconds to 300 seconds.

As the alkaline developer, for example, it is possible to use alkaline aqueous solutions such as aqueous solutions of inorganic alkalis such as sodium hydroxide, potassium hydroxide, sodium carbonate, sodium silicate, sodium metasilicate, and ammonia solutions, primary amines such as ethylamine and n-propylamine, secondary amines such as diethylamine and di-n-butylamine, tertiary amines such as triethylamine and methyldiethylamine, alcoholamines such as dimethylethanolamine and triethanolamine, quaternary ammonium salts such as tetramethylammonium hydroxide, tetraethylammonium hydroxide, and choline, cyclic amines such as pyrrole and piperidine, and other alkaline aqueous solutions. Furthermore, it is also possible to add an appropriate amount of alcohols such as isopropyl alcohol or nonionic-based surfactants to the above-described alkaline aqueous solutions and use the resultant mixture. Among these, as the developers, it is preferable to use a quaternary ammonium salt solution, and still more preferable to use a tetramethylammonium hydroxide solution and a choline solution. Furthermore, surfactants or other additives can be added to these developers. In place of the alkaline developer, it is also possible to use a method for performing development with an organic solvent such as butyl acetate and developing a portion where the alkaline dissolution rate of photoresist is not improved.

Next, the resist underlayer film is etched by using the formed resist pattern as a mask. The etching may be dry etching or wet etching, but is preferably dry etching.

In a case where the above-described inorganic film has been formed on the surface of the used semiconductor substrate, the inorganic film surface is exposed, and in a case where the above-described inorganic film has not been formed on the surface of the used semiconductor substrate, the semiconductor substrate surface is exposed. Thereafter, a step of processing the semiconductor substrate by a known method (dry etching method or other methods) can be carried out to manufacture a semiconductor device.

### EXAMPLES

Next, the contents of the present invention will be specifically described with reference to Examples, but the present invention is not limited thereto.

The weight-average molecular weight of each polymer illustrated in synthesis examples below is a measurement result by gel permeation chromatography (hereinafter, abbreviated as GPC). For the measurement, a GPC apparatus manufactured by Tosoh Corporation was used, and measurement conditions and other settings are as follows.
GPC column: Shodex KF803L, Shodex KF802, Shodex KF801 [registered trademark](Showa Denko K.K.)
Column temperature: 40° C.
Solvent: Tetrahydrofuran (THF)
Flow rate: 1.0 m1/min
Standard sample: polystyrene (manufactured by Tosoh Corporation)

### Synthesis Example 1

In a reaction vessel, 5.00 g of monoallyl diglycidyl isocyanuric acid (manufactured by SHIKOKU KASEI HOLDINGS CORPORATION), 5.32 g of 9,9-bis(4-hydroxyphenyl)fluorene (manufactured by Tokyo Chemical Industry Co., Ltd.), 0.96 g of adamantane carboxylic acid (manufactured by Tokyo Chemical Industry Co., Ltd.), and 0.21 g of tetrabutylphosphonium bromide (manufactured by ACROSS) were added to and dissolved in 79.00 g of propylene glycol monomethyl ether. The reaction vessel was purged with nitrogen, and then reacted at 105° C. for 24 hours to obtain a polymer solution. The polymer solution did not cause cloudiness or other appearance change even when cooled to room temperature, and had good solubility in propylene glycol monomethyl ether. As a result of GPC analysis, the polymer in the obtained solution had a weight-average molecular weight of 8000 in terms of standard polystyrene. The polymer obtained in the present synthesis example has structural units represented by Formulae (1a), (2a), and (3a).

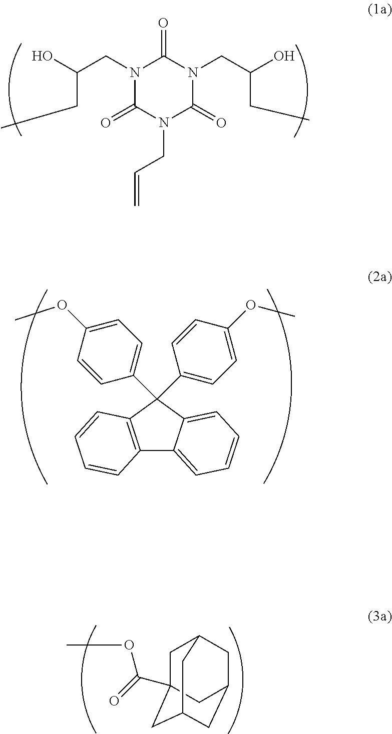

### Synthesis Example 2

In a reaction vessel, 10.00 g of 9,9-bis(4-glycidyloxyphenyl)fluorene (manufactured by Osaka Gas Chemicals Co., Ltd., product name: OGSOL PG), 5.32 g of 3,3′-dithiodipropionic acid (manufactured by Sakai Chemical Industry Co., Ltd., product name: DTDPA), 1.16 g of adamantane carboxylic acid (manufactured by Tokyo Chemical Industry Co., Ltd.), and 0.25 g of tetrabutylphosphonium bromide (manufactured by ACROSS) were added to and dissolved in 35.58 g of propylene glycol monomethyl ether. The reaction vessel was purged with nitrogen, and then reacted at 105° C. for 24 hours to obtain a polymer solution. The polymer solution did not cause cloudiness or other appearance change even when cooled to room temperature, and had good solubility in propylene glycol monomethyl ether. As a result of GPC analysis, the polymer in the obtained solution had a weight-average molecular weight of 9000 in terms of standard polystyrene. The polymer obtained in the present synthesis example has structural units represented by Formulae (1b), (2b), and (3a).

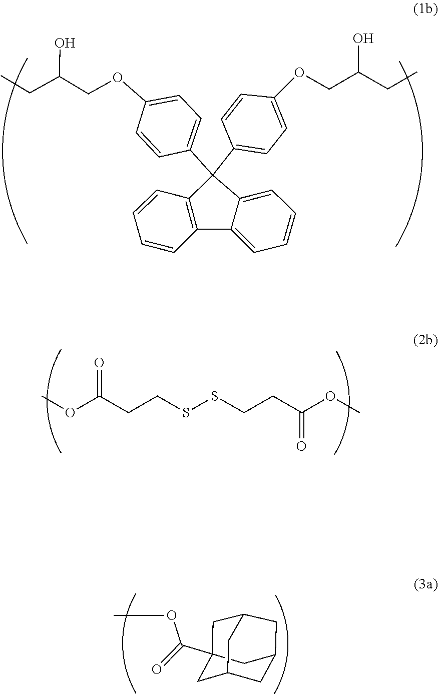

### Synthesis Example 3

In a reaction vessel, 5.00 g of 3′,6′-Bis(2-oxiranylmethoxy)spiro[9H-fluorene-9,9′-[9H]xanthene] (manufactured by Taoka Chemical Co., Ltd., trade name: TBIS-RXG), 1.82 g of 3,3′-dithiodipropionic acid (manufactured by Sakai Chemical Industry Co., Ltd., trade name: DTDPA), 0.55 g of adamantane carboxylic acid (manufactured by Tokyo Chemical Industry Co., Ltd.), and 0.25 g of tetrabutylphosphonium bromide (manufactured by ACROSS) were added to and dissolved in 30.00 g of propylene glycol monomethyl ether. The reaction vessel was purged with nitrogen, and then reacted at 105° C. for 24 hours to obtain a polymer solution. The polymer solution did not cause cloudiness or other appearance change even when cooled to room temperature, and had good solubility in propylene glycol monomethyl ether. As a result of GPC analysis, the polymer in the obtained solution had a weight-average molecular weight of 8000 in terms of standard polystyrene. The polymer obtained in the present synthesis example has structural units represented by Formulae (1c), (2b), and (3a).

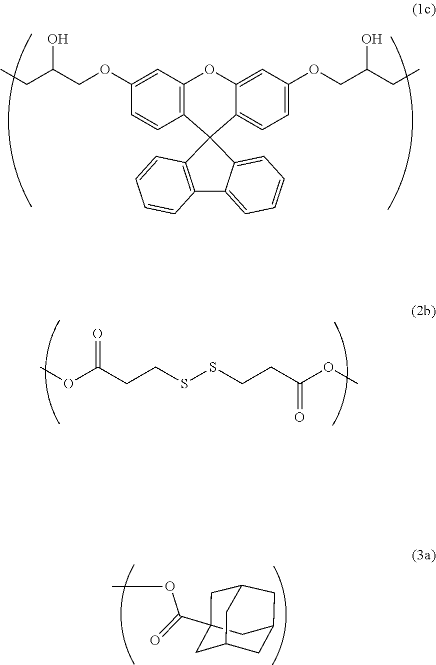

### Comparative Synthesis Example 1

In a reaction vessel, 3.00 g of monoallyl diglycidyl isocyanuric acid (manufactured by SHIKOKU KASEI HOLDINGS CORPORATION), 1.91 g of 3,3′-dithiodipropionic acid (manufactured by Sakai Chemical Industry Co., Ltd., trade name: DTDPA), 0.57 g of adamantane carboxylic acid (manufactured by Tokyo Chemical Industry Co., Ltd.), and 0.14 g of tetrabutylphosphonium bromide (manufactured by ACROSS) were added to and dissolved in 6.87 g of propylene glycol monomethyl ether. The reaction vessel was purged with nitrogen, and then reacted at 105° C. for 8 hours to obtain a polymer solution. The polymer solution did not cause cloudiness or other appearance change even when cooled to room temperature, and had good solubility in propylene glycol monomethyl ether. As a result of GPC analysis, the polymer in the obtained solution had a weight-average molecular weight of 5000 in terms of standard polystyrene. The polymer obtained in the present synthesis example has structural units represented by Formulae (1b), (2a), and (3a).

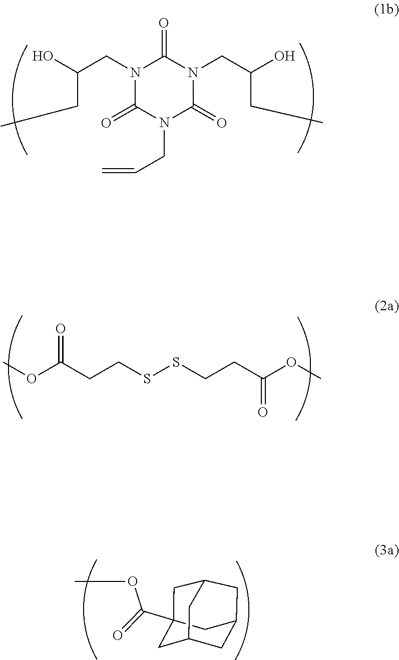

### Example 1

To 0.43 g (solid content: 16.4% by weight) of the polymer solution obtained in Synthesis Example 1 described above, 0.02 g of tetramethoxymethyl glycoluril (manufactured by Nihon Cytec Industries Inc.), 0.003 g of pyridinium phenol sulfonic acid, 44.5 g of propylene glycol monomethyl ether, and 4.99 g of propylene glycol monomethyl ether acetate were added and dissolved. The solution was then filtered by using a polyethylene microfilter having a pore size of 0.05 μm to prepare a resist underlayer film-forming composition for lithography.

### Example 2

To 0.47 g (solid content: 17.8% by weight) of the polymer solution obtained in Synthesis Example 2 described above, 0.02 g of tetramethoxymethyl glycoluril (manufactured by Nihon Cytec Industries Inc.), 0.003 g of pyridinium phenol sulfonic acid, 44.6 g of propylene glycol monomethyl ether, and 4.99 g of propylene glycol monomethyl ether acetate were added and dissolved. The solution was then filtered by using a polyethylene microfilter having a pore size of 0.05 μm to prepare a resist underlayer film-forming composition for lithography.

### Example 3

To 0.47 g (solid content: 18.3% by weight) of the polymer solution obtained in Synthesis Example 3 described above, 0.02 g of tetramethoxymethyl glycoluril (manufactured by Nihon Cytec Industries Inc.), 0.003 g of pyridinium phenol sulfonic acid, 44.6 g of propylene glycol monomethyl ether, and 4.99 g of propylene glycol monomethyl ether acetate were added and dissolved. The solution was then filtered by using a polyethylene microfilter having a pore size of 0.05 μm to prepare a resist underlayer film-forming composition for lithography.

### Comparative Example 1

To 0.47 g (solid content: 18.0% by weight) of the polymer solution obtained in Comparative Synthesis Example 1 described above, 0.02 g of tetramethoxymethyl glycoluril (manufactured by Nihon Cytec Industries Inc.), 0.003 g of pyridinium phenol sulfonic acid, 44.6 g of propylene glycol monomethyl ether, and 4.99 g of propylene glycol monomethyl ether acetate were added and dissolved. The solution was then filtered by using a polyethylene microfilter having a pore size of 0.05 μm to prepare a resist underlayer film-forming composition for lithography.

### [Elution Test in Photoresist Solvent]

Each of the resist underlayer film-forming composition in Example 1, Example 2, Example 3, and Comparative Example 1 was applied onto a silicon wafer as a semiconductor substrate by a spinner. The silicon wafer was disposed on a hot plate and baked at 205° C. for 1 minute to form a resist underlayer film (film thickness: 5 nm). These resist underlayer films were immersed in each of ethyl lactate and propylene glycol monomethyl ether, which are solvents used for the photoresist, and it has been confirmed that those resist underlayer films were insoluble in each of these solvents.

### [Formation of Positive-Type Resist Pattern by Electron Beam Drawing Apparatus]

Each of the resist underlayer film-forming compositions in Example 1, Example 2, Example 3, and Comparative Example 1 was applied onto a silicon wafer using a spinner. The silicon wafer was baked on a hot plate at 205° C. for 60 seconds to obtain a resist underlayer film having a film thickness of 5 nm. An EUV positive-type resist solution (containing a methacrylic polymer) was spin-coated on the resist underlayer film, and heated at 130° C. for 60 seconds to form an EUV resist film. The resist film was exposed under a predetermined condition using an electron beam lithography system (ELS-G130). After the exposure, the resist film was baked (PEB) at 100° C. for 60 seconds, cooled on a cooling plate to room temperature, and developed with an alkaline developer (2.38% TMAH), and then a line-and-space resist pattern with a CD of 25 nm and a pitch of 50 nm was formed. A scanning electron microscope (CG4100 manufactured by Hitachi High-Technologies Corporation) was used for measuring the length of the resist pattern. In the formation of the resist pattern, LWR of a 25 nm CD was compared. The results are shown in Table 1.

TABLE 1

| | LWR of 25 nm CD |
|---|---|
| Example 1 | 3.44 nm |
| Example 2 | 3.42 nm |
| Example 3 | 3.42 nm |
| Comparative Example 1 | 3.56 nm |

In all of Example 1, Example 2, and Example 3, favorable LWR was exhibited as compared with Comparative Example 1.

1. A resist underlayer film-forming composition for EB or EUV lithography, the resist underlayer film-forming composition comprising:
a polymer containing a fluorene structure; and
a solvent.

2. The resist underlayer film-forming composition for EB or EUV lithography according to claim 1, wherein
the polymer contains a partial structure represented by Formula (1), 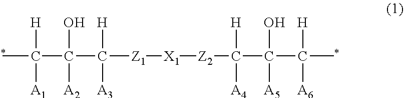
wherein, X₁ represents a divalent organic group having a fluorene structure,
Z₁ and Z₂ each independently represent a single bond, —O—, —C(═O)O—, or —O—CₘH₂ₘ—O— (where, m represents an integer of 1 to 6),
A₁, A₂, A₃, A₄, As, and A₆ each independently represent a hydrogen atom, a methyl group, or an ethyl group, and
* represents a bond.

3. The resist underlayer film-forming composition for EB or EUV lithography according to claim 2, wherein
X₁ in Formula (1) represents a divalent organic group represented by Formula (1-A) or (1-B), 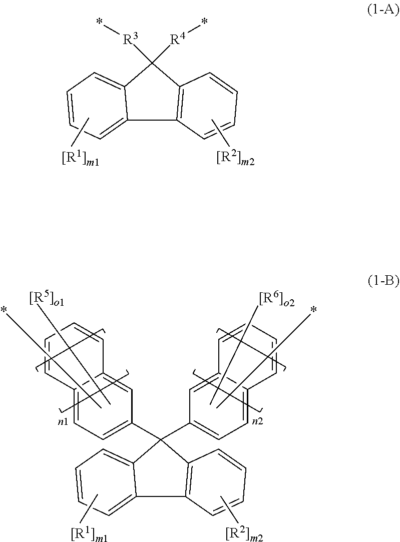
wherein, R¹, R², R⁵, and R⁶ each independently represent a hydroxy group, an acyl group having 1 to 6 carbon atoms, an alkoxy group having 1 to 6 carbon atoms, an alkoxycarbonyl group having 1 to 6 carbon atoms, an alkyl group having 1 to 10 carbon atoms, an aryl group having 6 to 20 carbon atoms, an alkenyl group having 2 to 20 carbon atoms, or an alkynyl group having 2 to 10 carbon atoms, and the acyl group, the alkoxy group, the alkoxycarbonyl group, the alkyl group, the aryl group, the alkenyl group, and the alkynyl group may have one or more groups selected from the group consisting of an amino group, a nitro group, a cyano group, a hydroxy group, a glycidyl group, and a carboxyl group,
R³ and R⁴ each independently represent a single bond or an alkylene group having 1 to 10 carbon atoms,
m1 and m2 each independently represent an integer of 0 to 4,
n1 and n2 each independently represent 0 or 1,
in a case where n1 is 0, o1 represents an integer of 0 to 4, and in a case where n1 is 1, o1 represents an integer of 0 to 6,
in a case where n2 is 0, o2 represents an integer of 0 to 4, and in a case where n2 is 1, o2 represents an integer of 0 to 6,
in a case where a plurality of R¹'s, a plurality of R²'s, a plurality of R³'s, a plurality of R⁴'s, a plurality of R⁵'s, and a plurality of R⁶'s are present, each R¹, each R², each R³, each R⁴, each R⁵, and each R⁶ may be the same as or different from each other,
one R⁵ and one R⁶ may be combined to form an —O— bond, and
* represents a bond.

4. The resist underlayer film-forming composition for EB or EUV lithography according to claim 2, wherein
the polymer further contains at least one of a partial structure represented by Formula (2-1) or a partial structure represented by Formula (2-2), 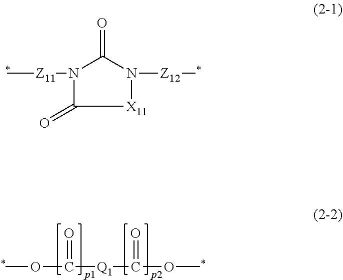
wherein, X₁₁ represents a group represented by any one of Formula (2-1-1), (2-1-2), or (2-1-3),
Z₁ and Z₁₂ each independently represent a single bond or a divalent group represented by Formula (2-1-4),
Q₁ represents a single bond or a divalent organic group, and
p1 and p2 each independently represent 0 or 1, 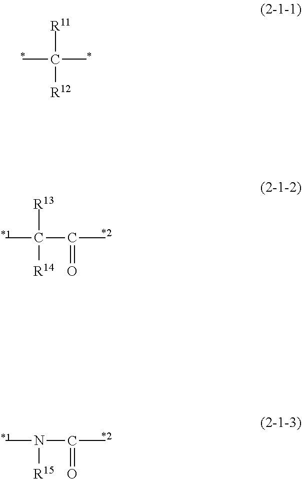
wherein, R¹¹ to R¹⁵ each independently represent a hydrogen atom, an alkyl group having 1 to 10 carbon atoms, which may be interrupted by an oxygen atom or a sulfur atom, an alkenyl group having 2 to 10 carbon atoms, which may be interrupted by an oxygen atom or a sulfur atom, an alkynyl group having 2 to 10 carbon atoms, which may be interrupted by an oxygen atom or a sulfur atom, a benzyl group, or a phenyl group, where the phenyl group may be substituted with at least one monovalent group selected from the group consisting of an alkyl group having 1 to 6 carbon atoms, a halogen atom, an alkoxy group having 1 to 6 carbon atoms, a nitro group, a cyano group, and an alkylthio group having 1 to 6 carbon atoms, R¹¹ and R¹² may be bonded to each other to form a ring having 3 to 6 carbon atoms, R¹³ and R¹⁴ may be bonded to each other to form a ring having 3 to 6 carbon atoms, * represents a bond, * 1 represents a bond bonded to a carbon atom, *2 represents a bond bonded to a nitrogen atom, 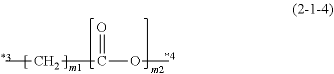
wherein, m1 represents an integer of 1 to 4, m2 represents 0 or 1, *3 represents a bond bonded to a nitrogen atom, and *4 represents a bond.

5. The resist underlayer film-forming composition for EB or EUV lithography according to claim 1, the resist underlayer film-forming composition further comprising a crosslinking agent.

6. The resist underlayer film-forming composition for EB or EUV lithography according to claim 1, the resist underlayer film-forming composition further comprising a curing catalyst.

7. The resist underlayer film-forming composition for EB or EUV lithography according to claim 1, wherein the resist underlayer film-forming composition is used to form a resist underlayer film for EB or EUV lithography, the resist underlayer film having a film thickness of 10 nm or less.

8. A resist underlayer film for EB or EUV lithography,
wherein the resist underlayer film is a cured product formed from the resist underlayer film-forming composition for EB or EUV lithography according to claim 1.

9. A semiconductor processing substrate comprising:
a semiconductor substrate; and
the resist underlayer film for EB or EUV lithography according to claim 8.

10. A method for manufacturing a semiconductor element,
the method comprising:
a step of forming a resist underlayer film on a semiconductor substrate by using the resist underlayer film-forming composition for EB or EUV lithography according to claim 1; and
a step of forming a resist film on the resist underlayer film.

11. A method for forming a pattern, the method comprising:
a step of forming a resist underlayer film on a semiconductor substrate by using the resist underlayer film-forming composition for EB or EUV lithography according to claim 1;
a step of forming a resist film on the resist underlayer film;
a step of irradiating the resist film with EB or EUV and developing the resist film to obtain a resist pattern; and
a step of etching the resist underlayer film by using the resist pattern as a mask.
